(19) United States
(12) Patent Application Publication
(10) Pub. No.: US 2025/0112026 A1
(43) Pub. Date: Apr. 3, 2025

(54) INVERTING IMPLANTER PROCESS MODEL FOR PARAMETER GENERATION

(71) Applicant: Applied Materials, Inc., Santa Clara, CA (US)

(72) Inventor: Richard Allen SPRENKLE, South Hamilton, MA (US)

(73) Assignee: Applied Materials, Inc., Santa Clara, CA (US)

(21) Appl. No.: 18/374,531

(22) Filed: Sep. 28, 2023

(51) Int. Cl. H01J 37/317; H01J 37/304

(52) U.S. Cl. CPC H01J 37/3171; H01J 37/304

(57) ABSTRACT

Techniques for inverting implanter process model for parameter generation are described. A method comprises receiving a set of process parameters and associated values for an ion implanter by an inverted control model, the inverted control model comprising an artificial neural network (ANN), predicting a set of control parameters and associated values for the ion implanter based on the set of process parameters and associated values by the inverted control model, and presenting the set of control parameters and associated values on a graphical user interface (GUI) of an electronic display. Other embodiments are described and claimed.

### BACKGROUND

An ion implanter is a device used in the semiconductor industry for doping or modifying the properties of materials. It is specifically designed to precisely introduce impurities, known as dopants, into target material to create semiconductor devices like transistors. The target material is usually a silicon wafer. The process involves accelerating ions to high speeds using an electric field and directing them towards the target material. The accelerated ions penetrate a substrate of the target material, displacing atoms and creating a controlled distribution of dopants in the substrate. The ion implanter typically comprises various components, such as an ion source to generate the desired ions, an accelerator to increase their energy, a mass analyzer to select the desired ions, and a beamline system to direct and focus the ion beam onto the substrate. The implanter settings, such as energy and current, are carefully controlled to achieve the desired dopant depth and concentration profiles. By precisely controlling the ion energy and dose, an ion implanter allows the customization of material properties. It plays a crucial role in the fabrication of integrated circuits, where different dopants create various regions necessary for device functionality, such as transistor gates, source, and drain regions. Overall, an ion implanter is a vital tool in the semiconductor industry for precisely introducing controlled impurities into materials, enabling the creation of advanced electronic devices.

### BRIEF DESCRIPTION OF THE SEVERAL VIEWS OF THE DRAWINGS

To easily identify the discussion of any particular element or act, the most significant digit or digits in a reference number refer to the figure number in which that element is first introduced.

FIG. 1 illustrates an ion implanter in accordance with one embodiment.

FIG. 2 illustrates an ion implanter in accordance with one embodiment.

FIG. 3 illustrates an inferencing system in accordance with one embodiment.

FIG. 4 illustrates a training system in accordance with one embodiment.

FIG. 5 illustrates a graphical user interface (GUI) in accordance with one embodiment.

FIG. 6 illustrates a process parameter in accordance with one embodiment.

FIG. 7A illustrates a set of parameters in accordance with one embodiment.

FIG. 7B illustrates a set of parameters in accordance with one embodiment.

FIG. 7C illustrates a set of parameters in accordance with one embodiment.

FIG. 8 illustrates a training device in accordance with one embodiment.

FIG. 9 illustrates a training system in accordance with one embodiment.

FIG. 10 illustrates an artificial neural network in accordance with one embodiment.

FIG. 11 illustrates a set of activation functions in accordance with one embodiment.

FIG. 12 illustrates a logic flow in accordance with one embodiment.

FIG. 13 illustrates a logic flow in accordance with one embodiment.

FIG. 14 illustrates computer readable medium (CRM) in accordance with one embodiment.

FIG. 15 illustrates a computing system in accordance with one embodiment.

FIG. 16 illustrates a communications system in accordance with one embodiment.

### DETAILED DESCRIPTION

Embodiments are generally directed to artificial intelligence (AI) and machine learning (ML) techniques for controlling a configuration or operation of an ion implanter. Some embodiments are particularly directed to AI and ML techniques for automatically tuning one or more components of an ion implanter for directing, controlling and shaping an ion beam as it travels from an ion source to a target material, such as a silicon wafer.

In one embodiment, for example, a software application may comprise instructions suitable for execution by logic circuitry or processing circuitry. The software application is generally arranged to assist in tuning operations for an ion implanter. The software application includes a graphical user interface (GUI) to present multiple GUI elements representing a set of control parameters for an ion implanter, with each control parameter having an associated information field to present one or more values for the control parameter. A control parameter generally corresponds to a hardware or software setting that controls a particular configuration or operation of a component of the ion implanter. The GUI also presents multiple GUI elements representing a set of process parameters for the ion implanter, with each process parameter having an associated information field to receive configurable values for the process parameter. A process parameter generally corresponds to a beam property, or a metric associated with a beam property, for an ion beam generated by the ion implanter.

An operator may use the GUI to select or enter defined threshold values in the information fields associated with process parameters of interest to the operator, referred to herein as a target set of process parameters. The software application implements a ML model trained to accept as input the target set of process parameters and associated values, and the ML model makes a prediction or inference for a set of control parameters and associated values that when applied to various components of the ion implanter produces an ion beam with beam properties that match the target set of process parameters. This provides a significant technical advantage over conventional techniques, since the operator does not need to manually and repetitively adjust control parameters in an attempt to arrive at a desired set of beam properties for a given application.

By way of background, ion implanters use a series of optical elements to extract ions, accelerate to precise energies, and form a stable uniform beam for implanting ions at specific depths in various substrates. These expensive machines must work over a wide range of ion mass and charge states, and manipulate the various optical elements to achieve a desired structure on a target material, such as a silicon wafer. As structures have become smaller and taller, operators need repeatable beam shapes with high uniformity, and that can achieve specific angle uniformity and distributions for exacting process requirements.

An operator for an ion implanter typically tunes various components of the ion implanter, sometimes referred to as “beamline” elements, by modifying one or more control parameters for the components to determine an effect on process parameters for the components. The components of an ion implanter shape a trajectory of an ion beam, focuses the ion beam, and ensures its stability and accuracy throughout the implantation process. Examples of components for the ion implanter may include electrostatic lenses, magnetic lenses, aperture systems, beam scanning systems, mass analyzers, Faraday cups, beam diagnostic tools, and other components.

Tuning an ion implanter is necessary for generating an ion beam with a set of target beam properties suitable for an intended application. Examples of tuning operations may include calibrating the ion implanter to ensure accurate measurements, adjusting a beam current to the desired level by changing the extraction voltage or aperture size, setting an appropriate ion energy to achieve the desired penetration depth in the target material by adjusting an accelerator voltage or a bias potential to control the ion energy to affect a depth of ion penetration and consequently the resulting doping profile, fine-tuning beam optics to ensure proper focusing and alignment by adjusting magnetic fields and beamline components to shape and direct the ion beam accurately onto the target area, attaining uniformity across the target area by adjusting the beam distribution for a beam scanning pattern or beam shaping devices, controlling a dose implanted by adjusting the beam current and the time of exposure to the ion beam, and other tuning operations. After tuning the ion implanter, a controller may conduct regular characterization tests to verify the achieved beam properties. This can involve metrology techniques such as secondary ion mass spectrometry (SIMS) or sheet resistance measurements.

An operator for an ion implanter typically tunes components of the ion implanter by modifying one or more control parameters for the components to determine an effect on one or more process parameters for the components. Each control parameter corresponds to a hardware or software setting for a component of the ion implanter. Examples of control parameters include a charge parameter, an energy parameter, an acceleration or deceleration parameter, a dopant and flow parameter, a diluent and flow parameter, a source parameter, an analyzer parameter, a corrector parameter, a suppression parameter, a focus parameter, a scan parameter, a quadrupole lens current parameter, a post-acceleration voltage parameter, and other control parameters. Each process parameter corresponds to a beam property for an ion beam generated by the ion implanter. Examples of process parameters include a beam height parameter, a beam width parameter, full half height maximum (FHHM) parameter, a vertical within device angle (VWIDA) parameter, a VWIDA mean (VWIDAM) parameter, a horizontal within device angle (HWIDA) parameter, a HWIDA mean (HWIDAM) parameter, a standard deviation of VWIDA (VWIDAS) parameter, a standard deviation of HWIDA mean (HWIDAS) parameter, a vacuum interface (VI) parameter, a width (full not half) parameter, a spotscore parameter, an energy parameter, a region of interest (ROI) current parameter, a uniformity parameter, and other process parameters.

Changing a control parameter for a component of the ion implanter affects a beam property of an ion beam as it implants ions into a substrate of a silicon wafer. This is typically a manually-intensive process, where the operator manually changes values for control parameters and evaluates changes in values for process properties important for a given application. This process continues in an iterative fashion until a particular configuration for the control parameters produces the desired output values for the process parameters.

An operator typically selects a set of control parameters and enters defined threshold values for each of the control parameters via a GUI for a software tool. The software tool generates a set of process parameters and values for the process parameters corresponding to the control parameters. By way of example, assume an operator desires to have the ion implanter generate an ion beam consistent with process parameters having values above a set of defined threshold values (or within a window around the defined threshold values), such as a process parameter (PP) 1 (PP1) of 17.5 mm, a PP2 of 0.7, and a PP3 of 0.07 (or better). Further assume the operator uses the GUI for a software application to select an input control vector subset with values for four control parameters, such as a control parameter (CP) 1 (CP1) of 52.56 kilovolts (kV), a CP2 of 6.750 kV, a CP3 of −39.80, and a CP4 of 3.491 kV. The software application may generate and display an output metrology vector subset of beam properties corresponding to the input control vector subset, such as a PP1 of 16.67, a PP2 of 0.6996, a PP3 of 0.07766, a PP4 of 0.000, a PP5 of 80.98, a PP6 of 150.6 mm, and a PP7 of 0.000. While the PP3 of 0.7760 meet the defined threshold value, the PP1 of 16.67 and PP2 of 0.6996 are below the defined threshold values. As such, the operator must manually and repeatedly adjust one or more values of the four control parameters until the beam property threshold values are all exceeded for the process parameters. This is a typically a tedious and time-consuming task for the operator, particularly when there is a large number of control parameters and process parameters.

Embodiments attempt to solve these and other problems. Rather than continuously modifying a set of control parameters in an attempt to determine a target set of process parameters, a software application implements a ML model trained to accept as input a target set of process parameters, and it makes a prediction or inference for a target set of control parameters that produce the target set of process parameters. Continuing with the previous example, assume an operator targets a set of process parameters, such as the PP1 of 17.5 mm, the PP2 of 0.7, and the PP3 of 0.07 (or better). In this case, the operator uses the GUI for the software tool to select an output metrology vector subset of beam properties. The ML model receives the output metrology vector subset as an input to the ML model. For example, assume the output metrology vector subset includes a PP1 of 18.53 mm, a PP2 of 0.7170, a PP3 of 0.07344, a PP4 of 0.000, a PP5 of 72.86, a PP6 of 190.0 mm, and a PP7 of 0.000 mm. The ML model of the controller receives as input the output metrology vector subset, and it predicts or infers an input control vector subset comprising a CP1 of 17.00 kV, a CP2 of 6.000 kV, a CP3 of 7.500, and a CP4 of 0.3750. The software application can then automatically configure one or more components of the ion implanter with the input control vector subset comprising a CP1 of 17.00 kV, CP2 of 6.000 kV, a CP3 of 7.500, and a CP4 of 0.3750 to cause the ion implanter to generate an ion beam with beam properties that match the output metrology vector subset of a PP1 of 18.53 mm, a PP2 of 0.7170, a PP3 of 0.07344, a PP4 of 0.000, a PP5 of 72.86, a PP6 of 190.0 mm, and a PP7 of 0.000 mm. By defining a target set of process parameters as input to the ML model, rather than the reverse, the ML model quickly and efficiently predicts a target set of control parameters that produces the target set of process parameters. As such, embodiments reduce an amount of time necessary to tune components of an ion implanter to meet specific requirements of an operator.

The use of AI and ML techniques for automatically tuning an ion implanter provides a significant technical solution that overcomes several technical challenges, including process repeatability, cross-tool process matching, decreased tune time, periodic maintenance endpoint detection, access to the full tool entitlement of beam shapes, and simplifying customer ability to quickly identify desired beam shape characteristics and establish appropriate tune window for reliable and repeatable tuning. Accordingly, tuning an ion implanter consumes less electronic resources, including: device resources such as compute and memory resources; device platform resources such as input/output (I/O) devices, peripheral components, and interfaces; network resources such as interconnect, wired and wireless bandwidth and associated protocol stack interfaces; cloud computing and data center resources; and other valuable and scarce computing and communications resources.

The present disclosure will now be described with reference to the attached drawing figures, wherein like reference numerals are used to refer to like elements throughout, and wherein the illustrated structures and devices are not necessarily drawn to scale. As utilized herein, terms “component,” “system,” “interface,” and the like are intended to refer to a computer-related entity, hardware, software (e.g., in execution), and/or firmware. For example, a component can be a processor (e.g., a microprocessor, a controller, or other processing device), a process running on a processor, a controller, an object, an executable, a program, a storage device, a computer, a tablet PC and/or a user equipment (e.g., mobile phone, etc.) with a processing device. By way of illustration, an application running on a server and the server can also be a component. One or more components can reside within a process, and a component can be localized on one computer and/or distributed between two or more computers. A set of elements or a set of other components can be described herein, in which the term “set” can be interpreted as “one or more.”

Further, these components can execute from various computer readable storage media having various data structures stored thereon such as with a module, for example. The components can communicate via local and/or remote processes such as in accordance with a signal having one or more data packets (e.g., data from one component interacting with another component in a local system, distributed system, and/or across a network, such as, the Internet, a local area network, a wide area network, or similar network with other systems via the signal).

As another example, a component can be an apparatus with specific functionality provided by mechanical parts operated by electric or electronic circuitry, in which the electric or electronic circuitry can be operated by a software application or a firmware application executed by one or more processors. The one or more processors can be internal or external to the apparatus and can execute at least a part of the software or firmware application. As yet another example, a component can be an apparatus that provides specific functionality through electronic components without mechanical parts; the electronic components can include one or more processors therein to execute software and/or firmware that confer(s), at least in part, the functionality of the electronic components.

Use of the word exemplary is intended to present concepts in a concrete fashion. As used in this application, the term “or” is intended to mean an inclusive “or” rather than an exclusive “or”. That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. In addition, the articles “a” and “an” as used in this application and the appended claims should generally be construed to mean “one or more” unless specified otherwise or clear from context to be directed to a singular form. Furthermore, to the extent that the terms “including”, “includes”, “having”, “has”, “with”, or variants thereof are used in either the detailed description or the claims, such terms are intended to be inclusive in a manner similar to the term “comprising.” Additionally, in situations wherein one or more numbered items are discussed (e.g., a “first X”, a “second X”, etc.), in general the one or more numbered items may be distinct or they may be the same, although in some situations the context may indicate that they are distinct or that they are the same.

As used herein, the term “circuitry” may refer to, be part of, or include a circuit, an integrated circuit (IC), a monolithic IC, a discrete circuit, a hybrid integrated circuit (HIC), an Application Specific Integrated Circuit (ASIC), an electronic circuit, a logic circuit, a microcircuit, a hybrid circuit, a microchip, a chip, a chiplet, a chipset, a multi-chip module (MCM), a semiconductor die, a system on a chip (SoC), a processor (shared, dedicated, or group), a processor circuit, a processing circuit, or associated memory (shared, dedicated, or group) operably coupled to the circuitry that execute one or more software or firmware programs, a combinational logic circuit, or other suitable hardware components that provide the described functionality. In some embodiments, the circuitry may be implemented in, or functions associated with the circuitry may be implemented by, one or more software or firmware modules. In some embodiments, circuitry may include logic, at least partially operable in hardware.

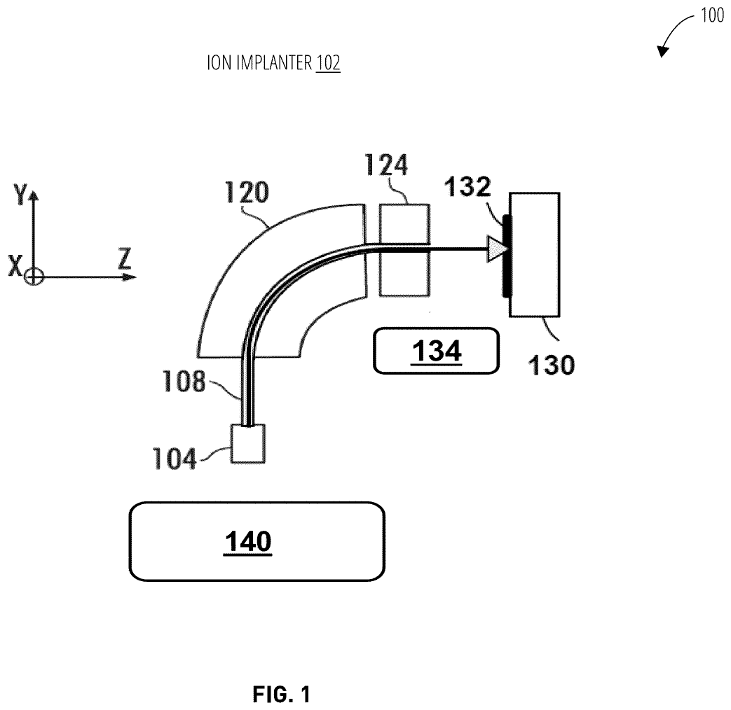

FIG. 1 depicts a schematic view of a system 100 including an ion implanter 102, in accordance with embodiments of the disclosure. The ion implanter 102 may include an ion source 104 for producing an ion beam 108, and a series of beam-line components. The ion source 104 may comprise a chamber for receiving a flow of gas and generating ions. The ion source 104 may also comprise a power source and an extraction electrode assembly (not shown) disposed near the chamber.

Suitable ions for ion beam 204 may include any ion species at a suitable ion energy, including ions such as phosphorous, boron, argon, indium, BF₂, nitrogen, oxygen, hydrogen, inert gas ions, and metallic ions, according to some non-limiting embodiments, with ion energy being tailored according to the exact ion species used.

The beam-line components may include, for example, a mass analyzer 120, and an end station 130, to house and manipulate a substrate 132 that is to intercept the ion beam 108. Thus, the ion source 104, as well as additional beamline components, will provide the ion beam 108 to the substrate 132, having a suitable ion species, ion energy, beam size, and beam angle, among other features, for implanting ions into the substrate 132.

In FIG. 1, in addition to a mass analyzer, according to various non-limiting embodiments, additional components that lie downstream to the ion source 104 may be included. These additional components may include components to accelerate ion beam 108, decelerate ion beam 108, focus ion beam 108, steer ion beam 108, collimate ion beam 108, mass filter ion beam 108, and scan ion beam 108, among other operations. Examples of components to accelerate an ion beam 108 include a DC accelerator column, an RF linear accelerator, and a tandem accelerator, as known in the art. Examples of components to scan the ion beam 108 include an electrostatic scanner or a magnetic scanner. An example of a component to focus the ion beam 108 includes a quadrupole lens.

The ion implanter 102 may further include one or more measurement components, arranged at one or more locations along the beamline, between ion source 104 and end station 130. For simplicity, these components are shown as beam measurement component 134. Examples of beam measurement component 134 include ion beam current measurement devices, ion beam angle measurement devices, ion beam energy measurement devices, and ion beam size measurement devices. In one example, the beam measurement component 134 may be a current detector such as a scanning detector, a closed loop current detector, and in particular a closed loop Faraday current detector (CLF), for monitoring beam current provided to the substrate 116. The beam measurement component may be disposed to intercept the ion beam 108 and may be configured to record beam current of the ion beam 108, either at a fixed position, or as a function of position. In some examples, the beam current of ion beam 108 may be measured for a region of interest (ROI), such as the region of the substrate 116.

The ion implanter 102 may also include a control system 140, which system may be included as part of ion implanter 102, to control operations such as adjustments to ion beam parameters. These parameters may include ion beam energy, ion beam size, ion beam current, ion beam angle, and so forth. In turn, the control system 140 may adjust and control these parameters by adjusting the operation of various components of the aforementioned beamline components of the ion implanter 102. The control system 140 may be included in the ion implanter 102 or may be coupled to the ion implanter 102 in order to implement the AI and ML techniques for automatically tuning one or more components of the ion implanter 102 as set forth in the embodiments to follow.

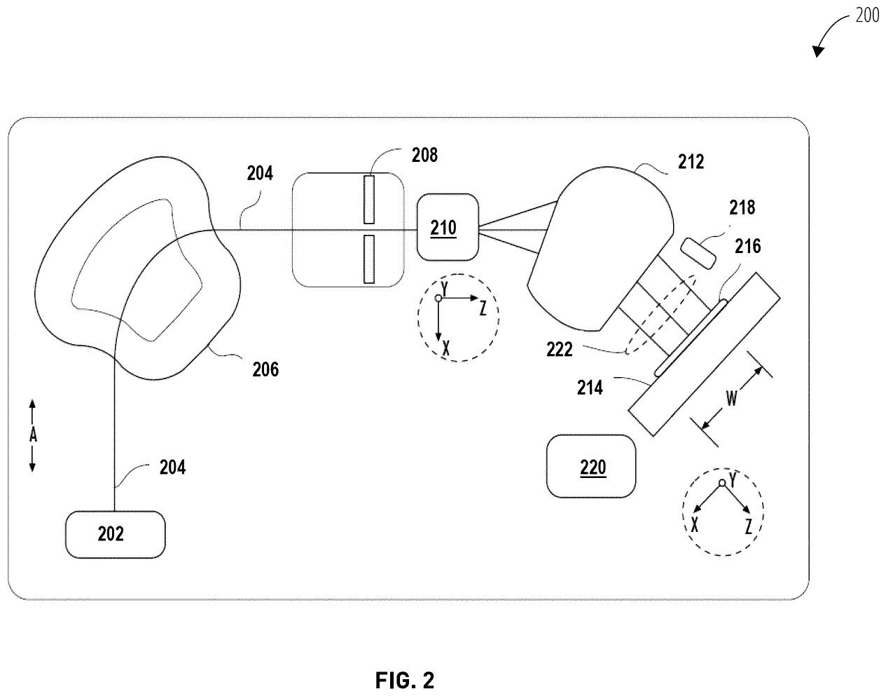

FIG. 2 depicts in block form of a beamline ion implanter, shown as the ion implanter 200, in accordance with various additional embodiments of the disclosure. The ion implanter 200 includes an ion source 202 configured to generate an ion beam 204. Suitable ions for ion beam 204 may include any ion species at a suitable ion energy, including ions such as phosphorous, boron, argon, indium, BF₂, nitrogen, oxygen, hydrogen, inert gas ions, and metallic ions, according to some non-limiting embodiments, with ion energy being tailored according to the exact ion species used.

The ion beam 204 may be provided as a spot beam scanned along a direction, such as the X-direction. In the convention used herein, the Z-direction refers to a direction of an axis parallel to the central ray trajectory of an ion beam 204. Thus, the absolute direction of the Z-direction, as well as the X-direction, where the X-direction is perpendicular to the Z-direction, may vary at different points within the ion implanter 200 as shown. The ion beam 204 may travel through a mass analysis component, shown as analyzer magnet 206, thence through a mass resolving slit 208, and through a collimator 212 before impacting a substrate 216 disposed on a substrate stage 214, which stage may reside within an end station (not separately shown). The substrate stage 214 may be configured to scan the substrate 216 at least along the Y-direction in some embodiments. In some embodiments, the substrate stage 214 may be configured to tilt about the X-axis or Y-axis, so as to change the beam angle of ion beam 204 when impacting substrate 216.

In the example shown in FIG. 2, the ion implanter 200 includes a beam scanner 210. When the ion beam 204 is provided as a spot beam, the beam scanner 210 may scan the ion beam 204 along the X-direction, producing a scanned ion beam, that enters the collimator 212 and exits in a fashion such that the ion beam 204 impacts the substrate 216 as a scanned ion beam 222 that scanned at the substrate along the X-direction (note the local X-direction in absolute sense may differ at different locations along the beamline as shown). Generally, the ion beam 204 may be scanned back and forth across a substrate 216 for any suitable number of scans, with an accompanying scanning of the substrate 216 in an orthogonal direction to the beam scan direction, until the targeted dose is implanted into substrate 216. The width of the resulting scanned spot beam may be comparable to the width W of the substrate 216 In various embodiments, the ion beam 204 may be scanned at a frequency of several Hz, 10 Hz, 100 Hz, up to several thousand Hz, or greater.

In various non-limiting embodiments, the ion implanter 200 may be configured to deliver ion beams for “low” energy or “medium” energy ion implantation, such as a voltage range of 1 kV to 300 kV, corresponding to an implant energy range of 1 keV to 300 keV for singly charged ions. As discussed below, the scanning of an ion beam provided to the substrate 116 may be adjusted depending upon calibration measurements before substrate ion implantation using a scanned ion beam. In other embodiments, the ion implanter 200 may be provided with an acceleration component, such as a DC acceleration column, an RF linear accelerator, or a tandem accelerator, where the ion implanter is capable to accelerate the ion beam 204 to energy of 1 MeV, 3 MeV, 5 MeV, or higher energy.

The ion implanter 200 may further include one or more measurement components, arranged at one or more locations along the beamline, between ion source 202 and substrate stage 214. For simplicity, these components are shown as beam measurement component 218. Examples of beam measurement component 218 include ion beam current measurement devices, ion beam angle measurement devices, ion beam energy measurement devices, and ion beam size measurement devices. In one example, the beam measurement component 218 may be a current detector such as a scanning detector, a closed loop current detector, and in particular a closed loop Faraday current detector (CLF), for monitoring beam current provided to the substrate 216. The beam measurement component may be disposed to intercept the ion beam 204 and may be configured to record beam current of the ion beam 204, either at a fixed position, or as a function of position. In some examples, the beam current of ion beam 204 may be measured for a region of interest (ROI), such as the region of the substrate 216.

The ion implanter 200 may also include a control system 220, which may be included as part of ion implanter 200, to control operations such as adjustments to ion beam parameters. These parameters may include ion beam energy, ion beam size, ion beam current, ion beam angle, and so forth. In turn, the control system 220 may adjust and control these parameters by adjusting the operation of various components of the aforementioned beamline components of the ion implanter 200. The control system 220 may be included in the ion implanter 200 or may be coupled to the ion implanter 200 in order to implement the AI and ML techniques for automatically tuning one or more components of the ion implanter 200 as set forth in the embodiments to follow.

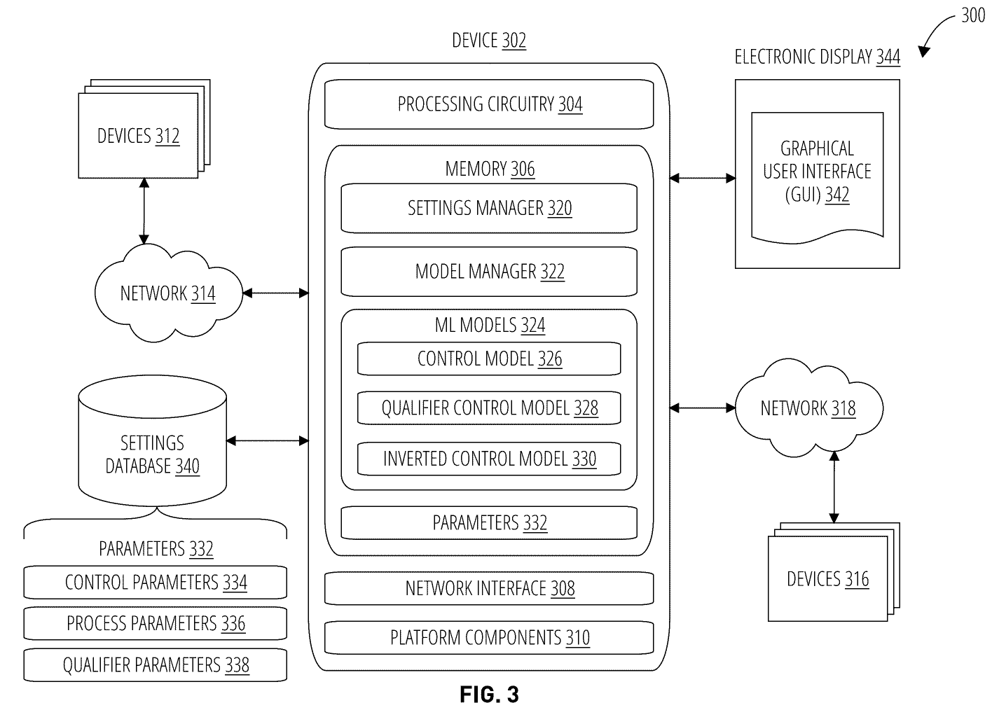

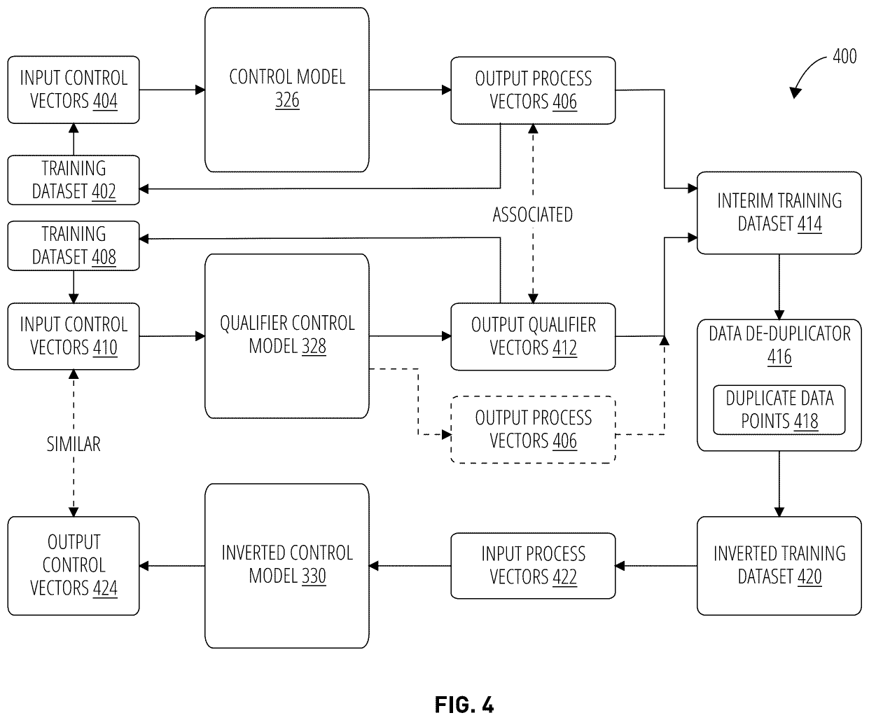

FIG. 3 illustrates an embodiment of an inferencing system 300. The inferencing system 300 may be suitable for implementing one or more embodiments as described herein. In one embodiment, for example, the inferencing system 300 may implement an inverted control model that is trained using training data generated from a control model. The control model is designed to predict a target set of process parameters from a target set of control parameters. The inverted control model does the reverse. The inverted control model predicts, suggests or infers a target set of control parameters from a target set of process parameters. In some cases, it becomes necessary to remove duplicates from the training data generated from the control model. In such cases, embodiments may implement techniques for identifying and removing duplicate metrics in a control model to create a training set for an inverted control model. A training system suitable for training an inverted control model is described with reference to FIG. 4.

As depicted in FIG. 3, the inferencing system 300 may comprise a device 302 communicatively coupled to a set of devices 312 via a network 314. The device 302 may also be communicatively coupled to a set of devices 316 via a network 318. It may be appreciated that the inferencing system 300 may have more or less devices than shown in FIG. 3 with a different network topology as needed for a given implementation. Embodiments are not limited in this context.

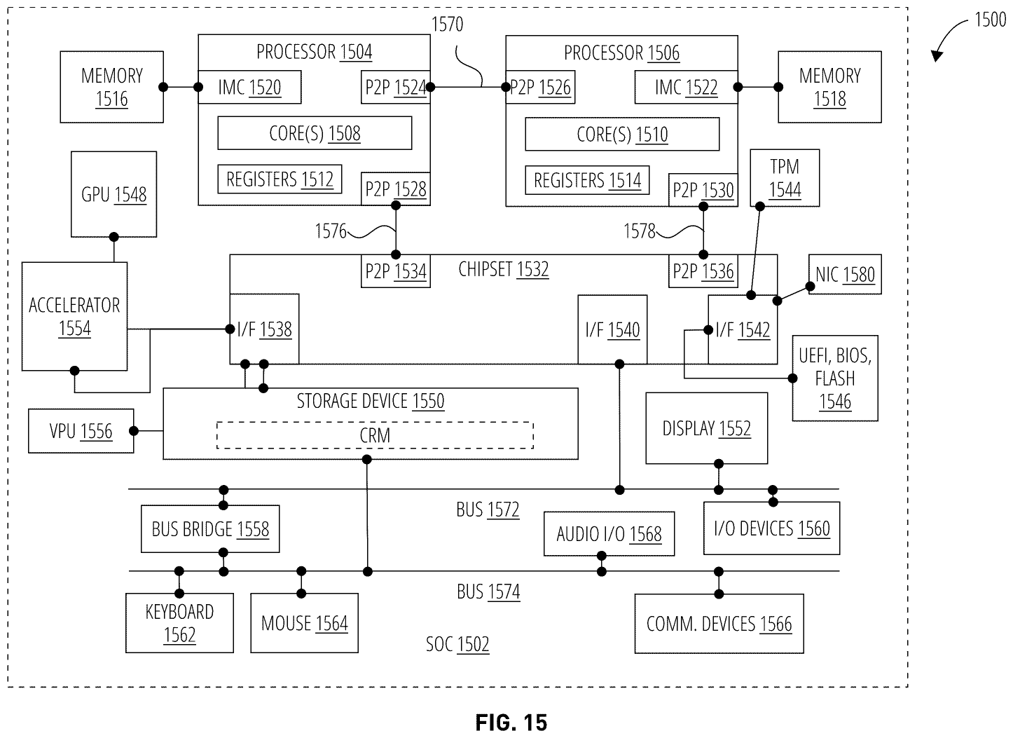

In various embodiments, the device 302 may comprise various hardware elements, such as a processing circuitry 304, a memory 306, a network interface 308, and a set of platform components 310. Similarly, the devices 312 and/or the devices 316 may include similar hardware elements as those depicted for the device 302. The device 302, devices 312, and devices 316, and associated hardware elements, are described in more detail with reference to a computing architecture 1500 as depicted in FIG. 15.

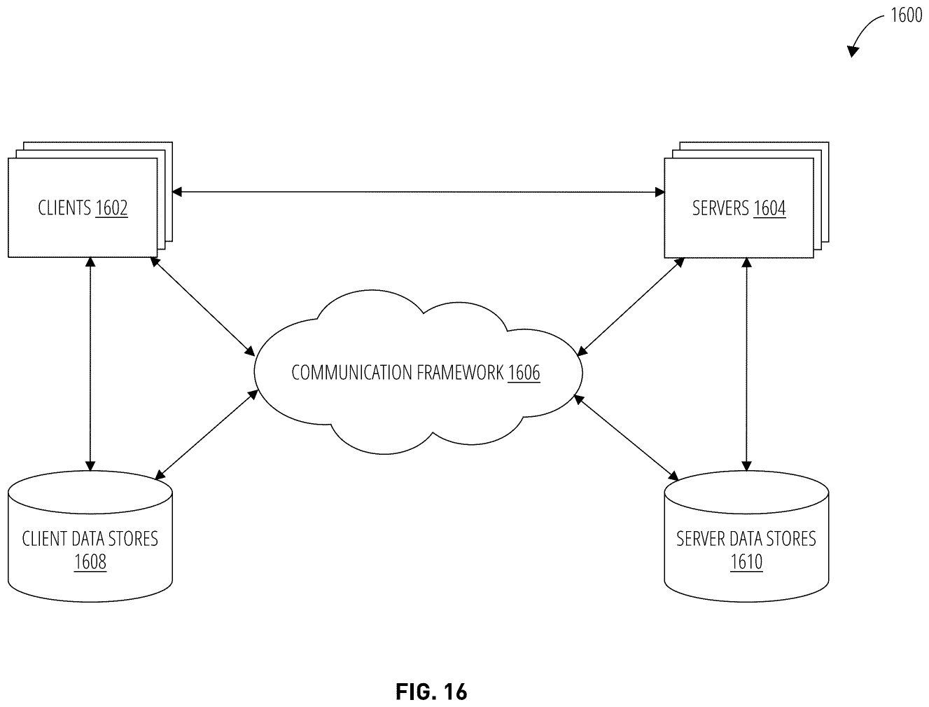

In various embodiments, the devices 302, 312 and/or 316 may communicate control, data and/or content information associated with the ion implanter 102 via one or both network 314, network 318. The network 314 and the network 318, and associated hardware elements, are described in more detail with reference to a communications architecture 1600 as depicted in FIG. 16.

The memory 306 may comprise a set of computer executable instructions that when executed by the processing circuitry 304, causes the processing circuitry 304 to manage a configuration or operation of the ion implanter 102. As depicted in FIG. 3, for example, the memory 306 may comprise a settings manager 320, a model manager 322, a set of ML models 324, and a set of parameters 332, among other parts. The ML models 324 include a control model 326, a qualifier control model 328, and an inverted control model 330. The parameters 332 include one or more control parameters 334, process parameters 336, and qualifier parameters 338. Additionally or alternatively, the parameters 332 are stored in a settings database 340 accessible by the device 302. Although FIG. 3 depicts the inferencing system 300 depicted as software elements executing on hardware elements, it may be appreciated that the software elements may be implemented as hardware elements or a combination of software elements and hardware elements as needed for a given set of design constraints. Embodiments are not limited in this context.

The settings manager 320 generally manages parameters 332 associated with one or more components of the ion implanter 102. The settings manager 320 may perform one or more change, read, update or delete (CRUD) operations to manage the parameters 332 stored in the settings database 340 or the memory 306. The settings manager 320 may also read parameters 332 from a data source, such as components of the ion implanter 102 or input data from the GUI 342 of the electronic display 344. The settings manager 320 may also write parameters 332 to a data sink, such as components of the ion implanter 102 or as output data for presentation on the GUI 342 of the electronic display 344. Read operations may be useful for retrieving a current set of parameters 332 from components of the ion implanter 102 or the GUI 342 for updating by one or more of the ML models 324. Write operations may be useful for sending an updated set of parameters 332 from the ML models 324 to components of the ion implanter 102 or the GUI 342. The read and write operations may facilitate automated calibration and tuning of the components of the ion implanter 102, such as during normal preventative maintenance (PM) cycles, responsive to lower production yields, or emergency disruptions. The read and write operations may also facilitate design and testing of the components of the ion implanter 102, such as for new applications.

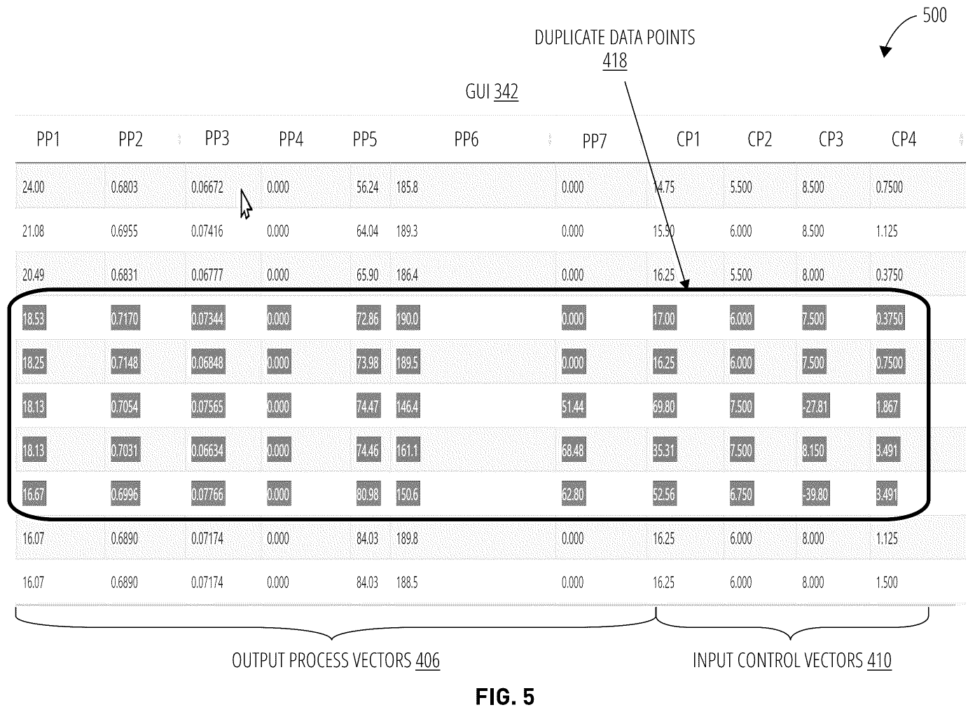

The model manager 322 generally manages various operations for one or more ML models 324. The ML models 324 have access to various parameters 332, including control parameters 334, process parameters 336, and qualifier parameters 338. The parameters 332 are stored in the memory 306 or in the settings database 340. In one embodiment, the ML models 324 present the control parameters 334, the process parameters 336 and/or the qualifier parameters 338 on the GUI 342 of an electronic display 344. An example of the GUI 342 is described with reference to FIG. 5.

An operator for the ion implanter 102 typically tunes components of the ion implanter 102 by modifying one or more control parameters 334 for the components to determine an effect on one or more process parameters 336 for the components. Each of the control parameters 334 corresponds to a hardware or software setting for a component of the ion implanter 102. Examples of control parameters 334 include without limitation a charge parameter, an energy parameter, an acceleration or deceleration parameter, a dopant and flow parameter, a diluent and flow parameter, a source parameter, an analyzer parameter, a corrector parameter, a suppression parameter, a focus parameter, a scan parameter, a quadrupole lens current parameter, a post-acceleration voltage parameter, and other control parameters. Embodiments are not limited to these examples.

Changing one or more control parameters 334 for one or more components of the ion implanter 102 affects a beam property of an ion beam as it implants ions into a substrate of a silicon wafer. In conventional systems, this is typically a manually-intensive process, where the operator manually changes values for control parameters 334 and evaluates changes in values for process parameters 336 important for a given application. This process continues in an iterative fashion until a particular configuration for the control parameters 334 produces the desired output values for the process parameters 336.

Embodiments automate tuning operations for the ion implanter 102 using one or more ML models 324 to avoid or reduce manual adjustments required by conventional systems. In general, a machine learning model is a mathematical representation or algorithmic structure that learns patterns and relationships from data in order to make predictions or take decisions without being explicitly programmed. It is a key component of machine learning, which is a subfield of artificial intelligence. A machine learning model is trained on a dataset containing input data and corresponding output labels or target values. During the training process, the model iteratively adjusts its internal parameters and learns from the data, aiming to minimize the difference between its predictions and the true values. Once trained, the model can be used to make predictions or decisions on new, unseen data. It takes the learned patterns and applies them to the input data to generate output predictions or estimates.

There are various types of machine learning models, each suited to different types of tasks and problem domains. Some common categories of machine learning models include: (1) regression models used to predict continuous numerical values, such as housing prices or stock prices; (2) classification models to classify inputs into different classes or categories based on their features, such as image classification or email spam filtering; (3) clustering models to group similar instances in an unsupervised manner, without prior knowledge of the classes or categories; (4) neural networks comprising interconnected nodes (or neurons) organized into layers, with each node applying functions to the data it receives; and (5) decision trees to represent decisions and their possible consequences as a tree-like structure and are commonly used for classification and regression tasks. These are just a few examples, and there are many other types and variations of machine learning models, each designed to tackle different types of problems and data structures.

As depicted in FIG. 3, the ML models 324 include a control model 326. In one embodiment, for example, the control model 326 is implemented as a feedforward model. A feedforward model is a type of neural network architecture where information flows through the network in one direction, from the input layer to the output layer, without any loops or cycles. It is called “feedforward” because the data passes through the network sequentially, layer by layer, without any feedback connections. In a feedforward model, the input data is fed into the input layer, and then it propagates forward through one or more hidden layers, where the data is transformed and processed. Finally, the transformed data is outputted by the output layer. Each layer is composed of multiple nodes (also called neurons) that perform calculations on the input data and apply linear or non-linear activation functions. The main purpose of a feedforward model is to map the input data to the desired outputs by learning the appropriate set of weights and biases associated with each node in the network. This learning process is typically accomplished through techniques such as backpropagation, where the model adjusts its parameters based on the difference between its predicted outputs and the ground truth labels. feedforward models are commonly used in various machine learning tasks, including classification, regression, and pattern recognition.

In one embodiment, the control model 326 is a feedforward model trained to receive an input control vector and predict an output process vector. An input control vector comprises an ordered list of values representing a set of control parameters 334 for the ion implanter 102. Each element of the input control vector corresponds to a specific value for each of the control parameters 334. The output process vector comprises an ordered list of values representing a set of process parameters 336 for the ion implanter 102 corresponding to the control parameters 334. Each element of the output process vector corresponds to a specific value for each of the process parameters 336.

The ML models 324 also include a qualifier control model 328. In one embodiment, for example, the qualifier control model 328 is a feedforward model similar to the control model 326. As with the control model 326, the qualifier control model 328 is a feedforward model trained to receive an input control vector and predict an output process vector. Similar to the control model 326, the input control vector comprises an ordered list of values representing a set of control parameters 334 for the ion implanter 102. Unlike the control model 326, however, the output process vector comprises an ordered list of values representing one or more qualifier parameters 338 associated with the set of process parameters 336 that are output from the control model 326.

Although the device 302 includes a separate control model 326 and qualifier control model 328, it may be appreciated that the control model 326 and the qualifier control model 328 can be combined into a single feedforward model. This is a design consideration based on expected performance of separate models versus a blended model.

The ML models 324 further include an inverted control model 330. The inverted control model 330 is designed to invert the input-output pairs of the control model 326. In one embodiment, for example, the inverted control model 330 is a feedforward model that inverts operations for the control model 326. More particularly, the inverted control model 330 is a feedforward model trained to receive an input process vector and predict an output control vector. An input process vector comprises an ordered list of values representing a set of process parameters 336 for the ion implanter 102. Each element of the input process vector corresponds to a specific value for each of the process parameters 336. The output control vector comprises an ordered list of values representing a set of control parameters 334 for the ion implanter 102 corresponding to the process parameters 336. Each element of the output control vector corresponds to a specific value for each of the control parameters 334. The output control vector represents control parameters 334 that when implemented by one or more components of the ion implanter 102 causes the ion implanter 102 to generate an ion beam with beam properties that match the process parameters 336.

Inverting a feedforward model, such as the control model 326, to form the inverted control model 330 is a challenging task, especially because feedforward models are not designed for direct inversion. When input layer variation of the control model 326 always results in unique outputs, the control model 326 can run forward to create a training set where the outputs become the inputs. The inverted control model 330 is then trained using the training set to receive the input process vector to predict the output control vector. In some cases, however, the control model 326 may map multiple input control vectors to duplicate output process vectors.

In general, a function is invertible only if each input has a unique output. By way of example, assume a set of x values comprising [1, 2, 3, 4] are input for a function h that produces a set of y values comprising [2, 1, 2, 5]. In this case, multiple x values 1 and 3 map to a single y value of 2. When inverted, the set of x values [1, 2, 5] are input for a function h⁻¹ that produces a set of y values comprising [1, 2, 3, 4]. The x value of 2 maps to multiple y values 1 and 3. This means that h⁻¹ is not a function, and therefore h is non-invertible.

When the control model 326 maps multiple input control vectors to duplicate output process vectors, the control model 326 is considered non-invertible since the inverted mapping is non-deterministic. Inverting the feedforward model for the control model 326 introduces ambiguity and therefore makes it difficult to obtain a unique inverse mapping. In this case, the control model 326 will produce training data that is not suitable for training the inverted control model 330.

To make the training data invertible, the model manager 322 is designed to initiate a model de-duplication process to identify duplicate output process vectors from the control model 326. The ML models 324 then either: (1) eliminates the duplicate output process vectors from a training set for the control model 326; or (2) adds one or more qualifier parameters 338 to segregate the duplicate output process vectors. Once the model de-duplication process terminates, the resulting training data contains data points that map each input control vector to exactly one output process vector, similar to a function.

The model de-duplication process begins by identifying duplicate output process vectors for multiple input control vectors. Identifying duplicate outputs produced by the control model 326 can be done in various ways depending on the specific problem and the nature of the output data. Once duplicate data points are identified, they are removed from the training data.

In one embodiment, for example, the model manager 322 uses the control model 326 and/or the qualifier control model 328 to generate a training dataset comprising millions of data points based on a balanced distribution across an entire input space. Each data point comprises an output process vector combining both process parameters 336 and qualifier parameters 338. As previously described, the qualifier parameters 338 may represent one or more performance indicators for components of the ion implanter 102. Examples of qualifier parameters 338 include performance indicators such as tune time, stability, tunability, stress vector impact, and other performance indicators. Elements of the output process vectors are rounded to suitable resolution to facilitate sorting and identification of duplicates. Duplicates are assessed via two different similarity scores which are designed to measure of distance between vectors. The first similarity score uses only the output process vectors. The second similarity score uses both the output process vectors and the output qualifier vectors. This large training set will be used to teach the inverted control model 330 using several strategies, such as: (1) a set of points where process parameters 336 are sufficiently different while ignoring qualifier parameters 338 in the vector distance but the qualifier parameters 338 are used to discard duplicates; or (2) a set of points where a combination of the process parameters 336 and the qualifier parameters 338 are sufficiently different but the qualifier parameters 338s are used to discard duplicates. In general, the former strategy may generate more duplicates while the latter strategy less duplicates. Each strategy is assessed for performance, with the highest performance model being chosen for a given implementation. An example of a de-duplication process is described in more detail with reference to FIG. 4.

Once the model manager 322 modifies the training dataset to identify and remove duplicates, the training dataset is suitable for training the inverted control model 330. The trained inverted control model 330 predicts a unique set of control parameters 334 for a given set of process parameters 336.

In operation, the memory 306 stores instructions that, when executed by the processing circuitry 304, causes the processing circuitry 304 to receive a set of process parameters 336 and associated values for an ion implanter 102 by an inverted control model 330. The inverted control model 330 may comprise an ML model such as an artificial neural network (ANN). The inverted control model 330 predicts a set of control parameters 334 and associated values for the ion implanter 102 based on the set of process parameters 336 and associated values. The settings manager 320 of the device 302 presents the set of control parameters 334 and associated values on a GUI 342 of an electronic display 344. An example of the GUI 342 is described with reference to FIG. 5.

In one embodiment, the inverted control model 330 is trained on an inverted training dataset generated from a control model 326 trained to receive input control vectors and predict output process vectors, where duplicate data points are removed from the inverted training dataset. More particularly, the inverted control model 330 is trained on an inverted training dataset generated from a control model 326 trained to receive input control vectors and predict output process vectors and a qualifier control model 328 trained to receive the input control vectors and predict output qualifier vectors, where duplicate data points are removed from the inverted training dataset based on one or more qualifier parameters 338 from the output qualifier vectors. The training phase of the control model 326, the qualifier control model 328, and the inverted control model 330 is further described with reference to FIG. 4.

In one embodiment, each of the control parameters 334 corresponds to a hardware or software set that controls a configuration or operation of a component of the ion implanter 102. Non-limiting examples of the control parameters 334 include a charge parameter, an energy parameter, an acceleration or deceleration parameter, a dopant and flow parameter, a diluent and flow parameter, a source parameter, an analyzer parameter, a corrector parameter, a suppression parameter, a focus parameter, a scan parameter, a quadrupole lens current parameter, or a post-acceleration voltage parameter.

In one embodiment, each of the process parameters 336 corresponds to a metric associated with a beam property for an ion beam generated by the ion implanter 102. Non-limiting examples of the process parameters 336 include a beam height parameter, a beam width parameter, full half height maximum (FHHM) parameter, a vertical within device angle (VWIDA) parameter, a VWIDA mean (VWIDAM) parameter, a horizontal within device angle (HWIDA) parameter, a HWIDA mean (HWIDAM) parameter, a standard deviation of VWIDA (VWIDAS) parameter, a standard deviation of HWIDA mean (HWIDAS) parameter, a vacuum interface (VI) parameter, a width (full not half) parameter, a spotscore parameter, an energy parameter, a region of interest (ROI) current parameter, or a uniformity parameter.

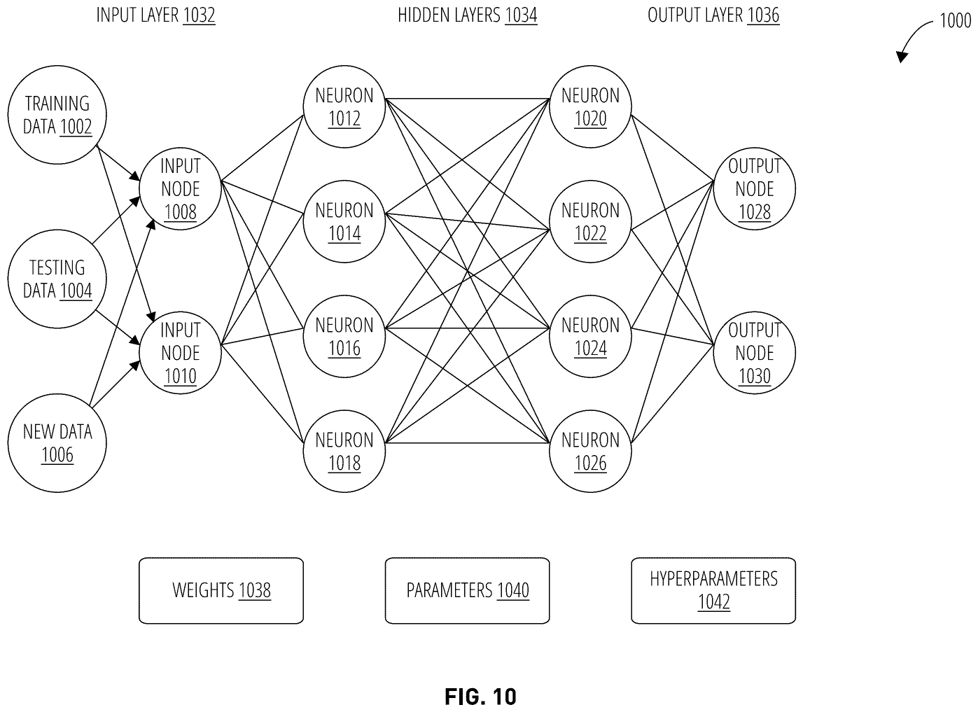

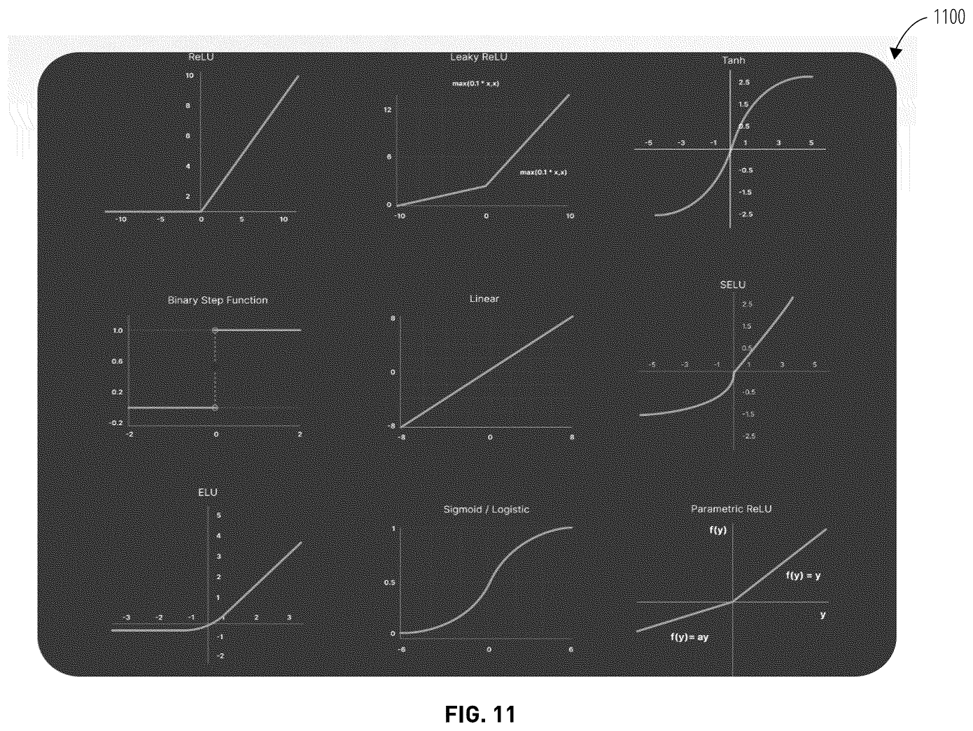

In one embodiment, the inverted control model 330 comprises a regression neural network that includes one input layer, one or more hidden layers, and an output layer, where each neuron in the one or more hidden layers performs computations on input data using a linear activation function to generate a continuous output value, the linear activation function includes a rectified linear unit (ReLU) function, a leaky ReLU function, or a parametric ReLU function. An example regression neural network for the inverted control model 330 is described in more detail with reference to FIG. 10. Examples of activation functions 1100 are described in more detail with reference to FIG. 11.

In one embodiment, the settings manager 320 may present the proposed control parameters 334 from the inverted control model 330 on the GUI 342. The operator can select a GUI element to regenerate the proposed control parameters 334 for the same set of input process parameters 336 to view different results. The operator can also modify values for the process parameters 336 to generate different proposed control parameters 334.

In one embodiment, the settings manager 320 may configure a component of the ion implanter 102 based on the set of control parameters 334 predicted by the inverted control model 330. For example, the settings manager 320 can present the set of control parameters 334 on the GUI 342 for review and approval by an operator. The operator can select a GUI element representing approval of the proposed control parameters 334. The GUI 342 generates a control directive and sends it to the settings manager 320. The settings manager 320 then automatically configures the appropriate components with the approved control parameters 334. Alternatively, the settings manager 320 may be configured to automatically update the appropriate components with the proposed control parameters 334 without explicit approval. Embodiments are not limited in this context.

In one embodiment, the settings manager 320 may write the control parameters 334 to memory for software controllers of components of the ion implanter 102 or send control signals to hardware controllers for the components of the ion implanter 102. The ion implanter 102 may generate an ion beam based on the configured control parameters 334.

FIG. 4 illustrates a training system 400. The training system 400 may be implemented by various devices from the system 100, the ion implanter 102, the ion implanter 200, or the inferencing system 300. In one embodiment, the training system 400 is implemented by the model manager 322 of the device 302 of the inferencing system 300. Embodiments are not limited to this example.

In one embodiment, for example, the model manager 322 trains a control model 326 on a first training dataset 402 that includes multiple data points. Each data point includes an input control vector and an output process vector. The input control vector includes values for control parameters 334 of an ion implanter 102. The output process vector comprises values for process parameters 336 of the ion implanter 102. The model manager 322 trains a qualifier control model 328 on a second training dataset 408 that includes the multiple data points of the first training dataset 402. Each data point includes the input control vector, the output process vector, and an output qualifier vector associated with the output process vector. The model manager 322 generates a third training dataset, such as an interim training dataset 414, using the trained control model 326 and the trained qualifier control model 328. The interim training dataset 414 includes multiple data points. Each data point includes an input control vector, an output process vector, and an output qualifier vector. A data de-duplicator 416 identifies duplicate data points 418 in the interim training dataset 414. The duplicate data points 418 comprise multiple data points having a shared output process vector for different input control vectors. The data de-duplicator 416 removes the duplicate data points 418 from the interim training dataset 414 based on an output qualifier vector for the duplicate data points 418. The data de-duplicator 416 then stores the interim training dataset 414 as an inverted training dataset 420. The model manager 322 then trains an inverted control model 330 on the inverted training dataset 420 that includes multiple data points, where each data point includes a unique input process vector corresponding to a unique output control vector, and therefore represents a function.

FIG. 4 depicts the training system 400 for the ML models 324, including the control model 326, the qualifier control model 328, and the inverted control model 330. In one embodiment, the ML models 324 are regression neural networks that include one input layer, one or more hidden layers, and an output layer, where each neuron in the one or more hidden layers performs computations on input data using a linear activation function to generate a continuous output value, the linear activation function includes a rectified linear unit (ReLU) function, a leaky ReLU function, or a parametric ReLU function.

In general, a regression neural network, also known as a feedforward neural network (FNN) or a multilayer perceptron (MLP), is a type of ANN commonly used for regression tasks in machine learning. Unlike classification tasks, which aim to assign inputs into discrete categories, regression tasks involve predicting continuous numerical values based on input features. In a regression neural network, the network architecture typically consists of an input layer, one or more hidden layers, and an output layer. Each layer comprises interconnected nodes, called neurons, that perform computations by applying weights to the input data and passing the result through an activation function. The network learns the optimal weights through a process called backpropagation, which adjusts the weights based on the difference between the predicted output and the actual target values. This iterative training process aims to minimize the prediction error or loss. During training, the regression neural network learns to approximate the underlying function that maps the input features to the continuous output values. The hidden layers enable the network to capture linear or non-linear relationships and extract relevant features from the input data. The number of hidden layers and the number of neurons in each layer are typically determined through experimentation and validation. Regression neural networks are versatile and can be applied to a wide range of regression tasks, such as predicting house prices, stock market trends, or customer demand. They are known for their ability to handle complex, high-dimensional datasets and can be enhanced by techniques like regularization, dropout, and batch normalization to improve generalization and prevent overfitting.

As previously described, the inverted control model 330 is trained on an inverted training dataset 420 generated from a control model 326 trained to receive input control vectors 404 and predict output process vectors 406, where duplicate data points are removed from the inverted training dataset 420. More particularly, the inverted control model 330 is trained on an inverted training dataset 420 generated from a control model 326 trained to receive input control vectors 404 and predict output process vectors 406 and a qualifier control model 328 trained to receive input control vectors 410 and predict output qualifier vectors 412, where duplicate data points are removed from the inverted training dataset 420 based on one or more qualifier parameters 338 from the output qualifier vectors 412.

Prior to training, a ML designer or the model manager 322 manages various sub-phases of the training system 400. For example, a ML designer or the model manager 322 defines a model architecture for the control model 326. The model architecture specifies a number of layers, a number of neurons in each layer, and the activation functions for the neurons. The ML designer or model manager 322 may also add regularization techniques like dropout or batch normalization to improve generalization and prevent overfitting. The ML designer or the model manager 322 selects an appropriate loss function based on the specific task. In one embodiment, for example, the specific task is a regression task, and therefore a mean squared error (MSE) loss function may be selected. The ML designer or the model manager 322 selects an optimization algorithm to update model weights during training to minimize the loss function, such as stochastic gradient descent (SGD), among others.

Once the control model 326 is defined, the model manager 322 pre-processes the data for the training dataset 402 to clean and organize the data, splits the data into training and validation sets, and performs any necessary data transformations or augmentations. The model manager 322 implements a training loop where data from the training dataset 402 iterates through the control model 326 to update the model weights based on the selected optimization algorithm. This is typically done in batches, where a batch of input data is fed through the network, the predictions are compared to the actual values using the loss function, and the gradients are computed and used to update the weights. Once trained, the model manager 322 periodically evaluates performance of the control model 326 on a separate validation set during training. This allows the model manager 322 to monitor model progress, detect overfitting, and make adjustments as needed. The model manager 322 may also perform hyperparameter tuning by experimenting with different hyperparameter settings such as learning rate, batch size, and regularization strength to find an optimal configuration that yields the best performance. Once training is complete, the model manager 322 evaluates the control model 326 on a separate test set to assess its performance on unseen data. This may include calculating relevant metrics such as accuracy, precision, recall, or MSE depending on the specific task.

As depicted in FIG. 4, the control model 326 is a FNN trained on labeled data from a training dataset 402. The model manager 322 feeds input control vectors 404 into the control model 326. The control model 326 generates output process vectors 406 based on the input control vectors 404. The output process vectors 406 are compared to labeled output process vectors 406 stored in the training dataset 402 for accuracy. This is typically done in batches, where a batch of input control vectors 404 is fed through the control model 326, the predictions of output process vectors 406 are compared to the actual values using the MSE loss function, and the gradients are computed and used to update the weights. Once the model manager 322 trains, tests and validates the control model 326, the model manager 322 feeds new data into the trained control model 326, and it stores the output process vectors 406 in an interim training dataset 414.

The model manager 322 trains the qualifier control model 328 in a manner similar to training the control model 326. The qualifier control model 328 has a FNN model architecture that is similar to the control model 326. Further, the input control vectors 404 from the training dataset 402 are the same or similar to the input control vectors 410 from the training dataset 408 used to train the qualifier control model 328. In one embodiment, for example, the input control vectors 410 have the same values representing the control parameters 334 as the input control vectors 404. In addition, the input control vectors 410 include one or more values for qualifier parameters 338. The model manager 322 trains the control model 326 and the qualifier control model 328 in parallel using similar training data. However, the model manager 322 trains the qualifier control model 328 to predict output qualifier vectors 412 associated with the output process vectors 406. The output qualifier vectors 412 include one or more values for the qualifier parameters 338. Since the training data is similar, the output process vectors 406 from the control model 326 and the output qualifier vectors 412 from the qualifier control model 328 are associated with each other. In other words, each of the output qualifier vectors 412 are associated with each of the output process vectors 406 since they are generated from the same or similar input data. Once the model manager 322 trains, tests and validates the qualifier control model 328, the model manager 322 feeds new unseen data into the trained qualifier control model 328. The model manager 322 stores the output qualifier vectors 412 as part of the interim training dataset 414, either separately from the output process vectors 406 or combined with the output process vectors 406 to form a combined vector.

Additionally or alternatively, the model manager 322 trains the qualifier control model 328 to predict both the output process vectors 406 and the output qualifier vectors 412 from the input control vectors 410. In this case, the model manager 322 only needs to train a single combined model. This is a design decision that balances training complexity with model performance characteristics targeted for a given implementation.

Once the interim training dataset 414 has a sufficient number of training data points suitable for a given implementation, the model manager 322 feeds the training data points from the interim training dataset 414 into a data de-duplicator 416. The data de-duplicator 416 implements a model de-duplication procedure to identify duplicate data points 418 from the output process vectors 406 from the control model 326 stored in the interim training dataset 414. The model manager 322 then either: (1) eliminates the duplicate data points 418 from the interim training dataset 414; or (2) adds one or more qualifier parameters 338 from the interim training dataset 414 to segregate the output process vectors 406 from the duplicate data points 418. Once the model manager 322 terminates execution of the data de-duplicator 416, the remaining data points from the interim training dataset 414 are stored as part of an inverted training dataset 420. Each data point in the inverted training dataset 420 maps each of the input control vectors 404 to exactly one of the output process vectors 406, and vice-versa.

The data de-duplicator 416 initiates the model de-duplication process to identify duplicate data points 418. Duplicate data points 418 comprise two or more data points with shared or common output process vectors 406 and with different input control vectors 404 (or input control vectors 410). For example, assume the interim training dataset 414 includes a first data point and a second data point. Further assume the first data point comprises a first input control vector and a first output process vector, and the second data point comprises a second input control vector and a second output process vector. When a difference between the first output process vector of the first data point and the second output process vector of the second data point are below (or above) a first defined threshold (e.g., a measured distance in vector space), they are considered shared output process vectors 406 or common output process vectors 406. The first defined threshold is a configurable value and is used to identify when the values of the output process vectors 406 are similar enough to each other to be considered substantially duplicate values. When a difference between the first input control vector of the first data point and the second input control vector of the second data point are above (or below) a second defined threshold (e.g., a measure distance in vector space), they are considered different input control vectors 404 (or input control vectors 410). The second defined threshold is a configurable value and is used to identify when the values of the input control vectors 404 or input control vectors 410 are different enough from each other to be considered substantially different values.

The data de-duplicator 416 identifies duplicate data points 418 using several different strategies. In one embodiment, the data de-duplicator 416 focuses on the output process vectors 406 for each data point. In another embodiment, the data de-duplicator 416 combines each of the output process vectors 406 with a corresponding one of the output qualifier vectors 412 for each data point to form combined vectors.

In one embodiment, the data de-duplicator 416 focuses on the output process vectors 406 for each data point. For example, the data de-duplicator 416 maps input control vectors 404 and output process vectors 406 from data points of the interim training dataset 414 to a shared vector space. The data de-duplicator 416 generates a similarity score for each of the input control vectors 404 and each of the output process vectors 406 based on a measure of distance between vectors in the shared vector space. The data de-duplicator 416 identifies duplicate data points 418 based on the similarity scores.

A similarity score typically refers to a measure of the similarity or distance between two vectors in a shared vector space. Vectors represent encoded representations of some input data. These vectors can be used for various purposes such as clustering, retrieval, or similarity search. To determine the similarity score between two vectors in the shared vector space, the data de-duplicator 416 uses different similarity measures. One example of a similarity measure is cosine similarity. Cosine similarity is a metric that calculates the cosine of the angle between the two vectors. Cosine similarity ranges from −1 to 1, where 1 indicates the vectors are identical, −1 indicates they are exactly opposite, and 0 implies they are orthogonal or independent. Another example of a similarity measure is Euclidean distance. This is the straight-line distance between two vectors in the shared vector space. It measures the geometric distance between the vectors and ranges from 0 to infinity. Smaller values typically indicate a higher similarity. Yet another example is Manhattan distance. Also known as an L1 distance or a city block distance, it calculates the sum of absolute differences between the corresponding elements of the two vectors. Similar to Euclidean distance, smaller values indicate higher similarity. Still another example is Minkowski distance. This is a generalized distance metric that includes the Euclidean distance and the Manhattan distance as special cases. The Minkowski distance takes an additional parameter that determines the degree of the distance function. The choice of similarity measure for a given implementation depends on the specific requirements of the task and the characteristics of the vectors in the shared vector space.

In one embodiment, the data de-duplicator 416 combines each of the output process vectors 406 with a corresponding one of the output qualifier vectors 412 for each data point to form combined vectors. For example, the data de-duplicator 416 combines an output process vector and an output qualifier vector for each data point of the interim training dataset 414 into a combined vector. The data de-duplicator 416 maps the input control vectors and the combined vectors from data points of the interim training dataset 414 to a shared vector space. The data de-duplicator 416 generates a similarity score for each input control vector and each combined vector based on a measure of distance between vectors. The data de-duplicator 416 identifies duplicate data points 418 based on the similarity scores.

Additionally or alternatively, the data de-duplicator 416 may implement different approaches for identifying duplicate data points 418 other than similarity measures. For example, the data de-duplicator 416 may compare values from the vectors directly. In another example, the data de-duplicator 416 can apply clustering algorithms, such as k-means, hierarchical clustering, or density-based spatial clustering of applications with noise (DBSCAN), can help group similar outputs together. If duplicate outputs exist, they are likely to form clusters in the output space. The data de-duplicator 416 can then analyze the clusters to identify duplicate data points 418. The data de-duplicator 416 can implement density estimation techniques, such as kernel density estimation or Gaussian mixture models to estimate the distribution of the output data. If there are regions of high density in the output space, it suggests the presence of duplicate outputs. Still another example is using hashing or unique identifiers. The data de-duplicator 416 can assign a unique hash or identifier to each output to help identify duplicates. By comparing the hashes or identifiers of the outputs, the data de-duplicator 416 can quickly detect duplicate data points 418 by finding matches. Embodiments are not limited to these examples.

When identifying duplicate data points 418, the data de-duplicator 416 determines that a difference value (e.g., a residual) between a first output process vector of a first data point and a second output process vector of a second data point from the interim training dataset 414 is below a first defined threshold value. The data de-duplicator 416 determines that a difference value between a first input control vector of the first data point and a second input control vector of the second data point is above a second defined threshold value. The data de-duplicator 416 identifies the first data point and the second data point as duplicate data points, the first input control vector and the second input control vector as the different input control vectors, and the first output process vector and the second output process vector as the shared output process vector.

Once the data de-duplicator 416 identifies a set of duplicate data points 418 in the interim training dataset 414, the data de-duplicator 416 can implement different strategies to address the duplicate data points 418. In one embodiment, the data de-duplicator 416 identifies a best data point from each of the duplicate data points 418 using the qualifier parameters 338, and eliminates the rest from the interim training dataset 414. In one embodiment, the data de-duplicator 416 retains the duplicate data points 418, and it sends a request to the model manager 322 to train the inverted control model 330 with a combination of the duplicate data points 418 and associated output qualifier vectors 412 to disambiguate or segregate the output process vectors 406 of the duplicate data points 418.

In one embodiment, the data de-duplicator 416 identifies a best data point from each of the duplicate data points 418 using the qualifier parameters 338, and eliminates the rest from the interim training dataset 414. For example, the data de-duplicator 416 eliminates the duplicate data points 418 from the interim training dataset 414 based on one or more output qualifier vectors 412 for the duplicate data points 418. The data de-duplicator 416 uses one or more qualifier parameters 338 from the output qualifier vectors 412 as a selection criteria to select one data point from each of the duplicate data points 418 to retain in the interim training dataset 414. For example, assume one of the qualifier parameters 338 is tune time. In this example, the data de-duplicator 416 selects a data point from each of the duplicate data points 418 that has the shortest tune time to retain in the interim training dataset 414. The remaining data points from each of the duplicate data points 418 that are not selected are eliminated from the interim training dataset 414. In this case, the data de-duplicator 416 removes output qualifier vectors 412 from the interim training dataset 414 prior to training the inverted control model 330.

In one embodiment, the data de-duplicator 416 retains the duplicate data points 418, and it sends a request to the model manager 322 to train the inverted control model 330 with a combination of the duplicate data points 418 and associated output qualifier vectors 412 to disambiguate or segregate the output process vectors 406 of the duplicate data points 418. For example, the data de-duplicator 416 retains the duplicate data points 418 in the interim training dataset 414, and also retains the output qualifier vectors 412 in the interim training dataset 414 prior to training the inverted control model.

Once the data de-duplicator 416 identifies and addresses each of the duplicate data points 418 in the interim training dataset 414, the remaining data points are stored as part of an inverted training dataset 420. The model manager 322 then iteratively trains the inverted control model 330 using input process vectors 422 from the inverted training dataset 420 to predict output control vectors 424, using a training procedure similar to the one described for the control model 326 and the qualifier control model 328. Once the model manager 322 trains, tests and validates the inverted control model 330, the model manager 322 outputs a control directive indicating the trained inverted control model 330 is ready for deployment to perform inferencing operations. The trained inverted control model 330 receives new data in the form of new input process vectors 422, and it predicts output control vectors 424 based on the input process vectors 422. The output control vectors 424 should be similar to the input control vectors 404 and/or the input control vectors 410 used for predicting the output control vectors 424 by the control model 326, thereby indicating that the inverted control model 330 represents an acceptable inverted mapping of the control model 326.

FIG. 5 illustrates an operating environment 500. The operating environment 500 illustrates an example of the GUI 342 for the device 302.

In one embodiment, for example, a software application such as the settings manager 320 and/or the model manager 322 may comprise instructions suitable for execution by logic circuitry or processing circuitry 304 of the device 302. The software application is generally arranged to assist in tuning operations for an ion implanter 102. The software application includes a GUI 342 to present multiple GUI elements representing a set of control parameters 334 for an ion implanter 102, with each of the control parameters 334 having an associated information field to present one or more values for each of the control parameters 334. A control parameter generally corresponds to a hardware or software setting that controls a particular configuration or operation of a component of the ion implanter 102. The GUI 342 also presents multiple GUI elements representing a set of process parameters 336 for the ion implanter 102, with each of the process parameters 336 having an associated information field to receive configurable values for each of the process parameters 336. A process parameter generally corresponds to a beam property, or a metric associated with a beam property, for an ion beam generated by the ion implanter 102.

An operator may use the GUI to select or enter defined threshold values in the information fields associated with process parameters 336 of interest to the operator, referred to herein as a target set of process parameters. The software application implements one or more ML models 324 trained to accept as input the target set of process parameters 336 and associated values, such as the inverted control model 330. The inverted control model 330 makes a prediction or inference for a set of control parameters 334 and associated values that when applied to various components of the ion implanter 102 produces an ion beam with beam properties that match the target set of process parameters 336. This provides a significant technical advantage over conventional techniques, since the operator does not need to manually and repetitively adjust control parameters 334 in an attempt to arrive at a desired set of beam properties for a given application.

As depicted in FIG. 5, the GUI 342 presents an example for the input control vectors 410 and an example for the output process vectors 406 of the control model 326. By way of example, assume an operator desires to have the ion implanter generate an ion beam consistent with process parameters 336 having values above a set of defined threshold values, such as a process parameter (PP) 1 (PP1) of 17.5 mm, a PP2 of 0.7, and a PP3 of 0.07 (or better). Further assume the operator uses the GUI 342 for the settings manager 320 to select an input control vector with values for four control parameters, such as a control parameter (CP) 1 (CP1) of 52.56 kilovolts (kV), a CP2 of 6.750 kV, a CP3 of −39.80, and a CP4 of 3.491 kV. The control model 326 may generate and display an output process vector with metrology for beam properties corresponding to the input control vector, such as a PP1 of 16.67, a PP2 of 0.6996, a PP3 of 0.07766, a PP4 of 0.000, a PP5 of 80.98, a PP6 of 150.6 mm, and a PP7 of 0.000. While the PP3 of 0.7760 meet the defined threshold value, the PP1 of 16.67 and PP2 of 0.6996 are below the defined threshold values. As such, the operator must manually and repeatedly adjust one or more values of the four control parameters until the beam property threshold values are all exceeded for the process parameters. This is a typically a tedious and time-consuming task for the operator, particularly when there is a large number of control parameters and process parameters.

The GUI 342 illustrates 5 different sets of input values for different input control vectors 404 that result in 5 different sets of output values for different output process vectors 406. However, the different sets of output values are within a relatively tight range of values sufficient to identify them as duplicates. Meanwhile, the different sets of input values are sufficiently distant from each other to identify them as not duplicates. As such, the data de-duplicator 416 identifies all 5 sets of input values and output values as duplicate data points 418.

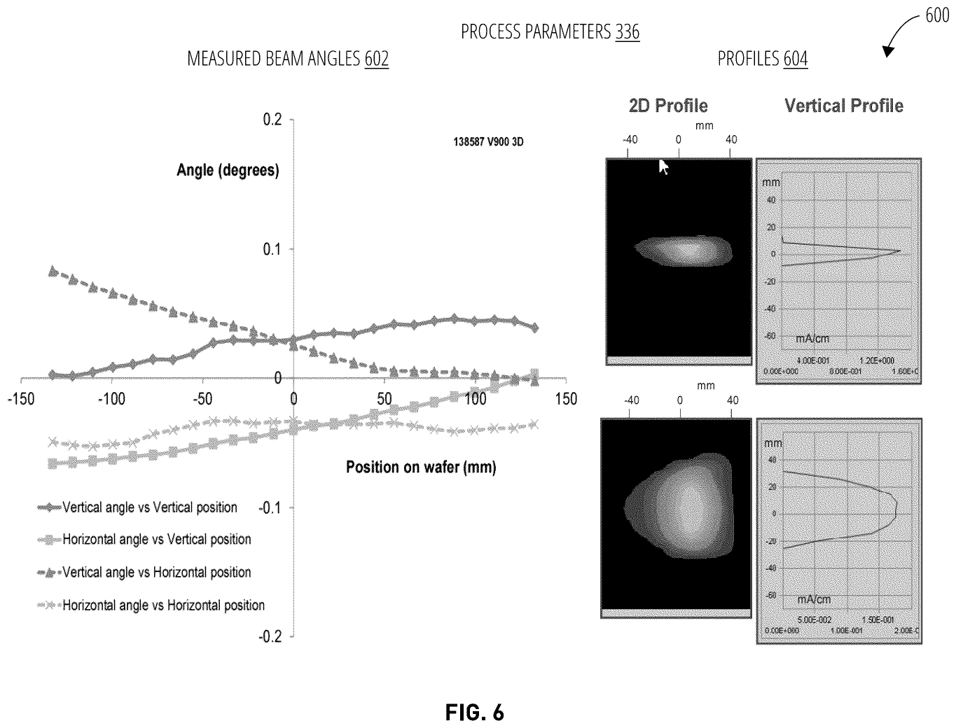

FIG. 6 illustrates an operating environment 600. The operating environment 600 is an example of the process parameters 336. As depicted in FIG. 6, the example process parameters 336 are measured beam angles 602 for the ion implanter 102. The measured beam angles 602 include plotted values for a vertical angle versus a vertical position, a horizontal angle versus the vertical position, a vertical angle versus a horizontal position, and the horizontal angle versus the horizontal position. The operating environment 600 also depicts a set of profiles 604 for measured beam angles 602. The profiles 604 include a two-dimensional (2D) profile and a vertical profile. The measured beam angles 602 and the profiles 604 illustrate significant differences between beam properties that affect an ion beam for the ion implanter 102.

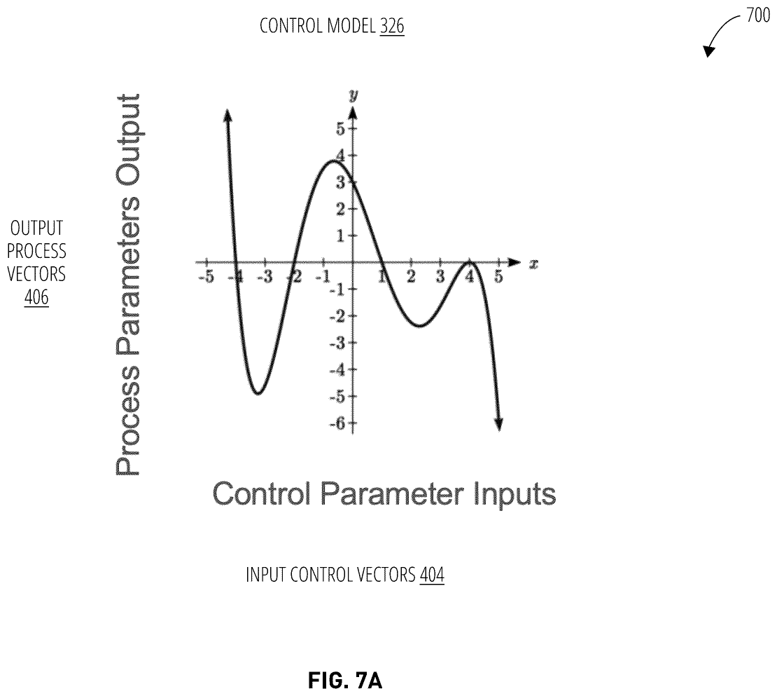

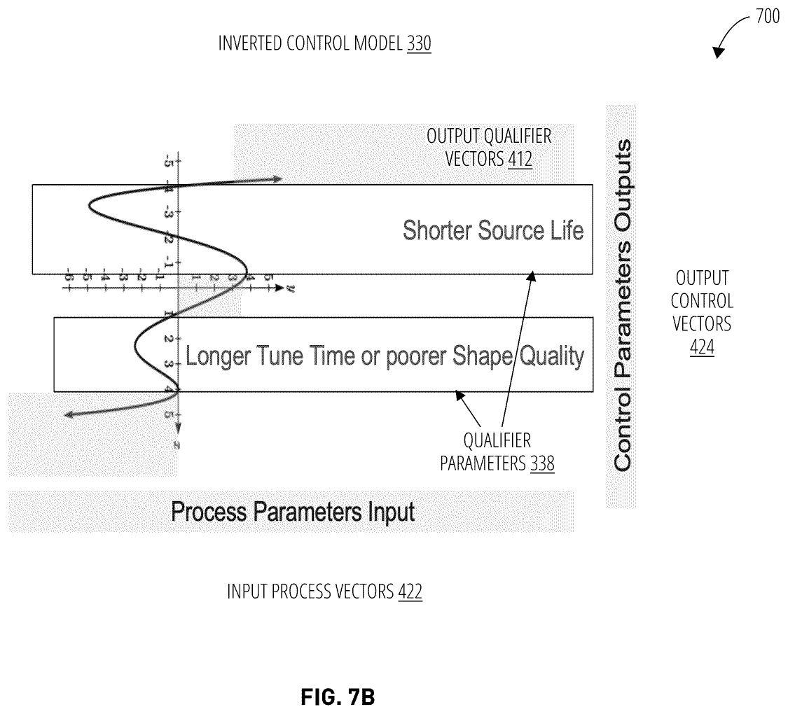

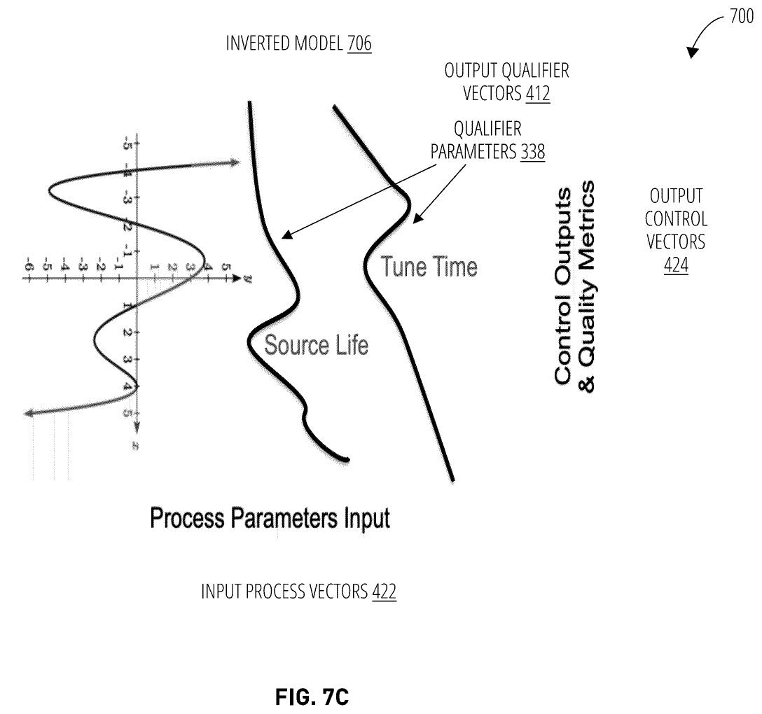

FIG. 7A illustrates an example for the operating environment 700. The operating environment 700 is an example of a graph of input control vectors 404 and output process vectors 406 for a control model 326. The graph illustrates a plotted line of continuous input values representing control parameters 334 and continuous output values representing process parameters 336.

FIG. 7B illustrates another example for the operating environment 700. The operating environment 700 is an example of input process vectors 422, output control vectors 424, and output qualifier vectors 412 for an inverted control model 330. The graph illustrates a plotted line of continuous input values representing process parameters 336 and continuous output values representing control parameters 334. The graph also illustrates regions for qualifier parameters 338 of the output qualifier vectors 412. Examples of qualifier parameters 338 include a longer tune time, a poorer shape quality, and a shorter source life.

FIG. 7C illustrates another example for the operating environment 700. The operating environment 700 is an example of input process vectors 422, output control vectors 424, and output qualifier vectors 412 for an inverted control model 330. The graph illustrates a plotted line of continuous input values representing process parameters 336 and continuous output values representing control parameters 334. The graph also illustrates continuous lines for multiple qualifier parameters 338 of the output qualifier vectors 412. Examples of the qualifier parameters 338 include tune time and source life.

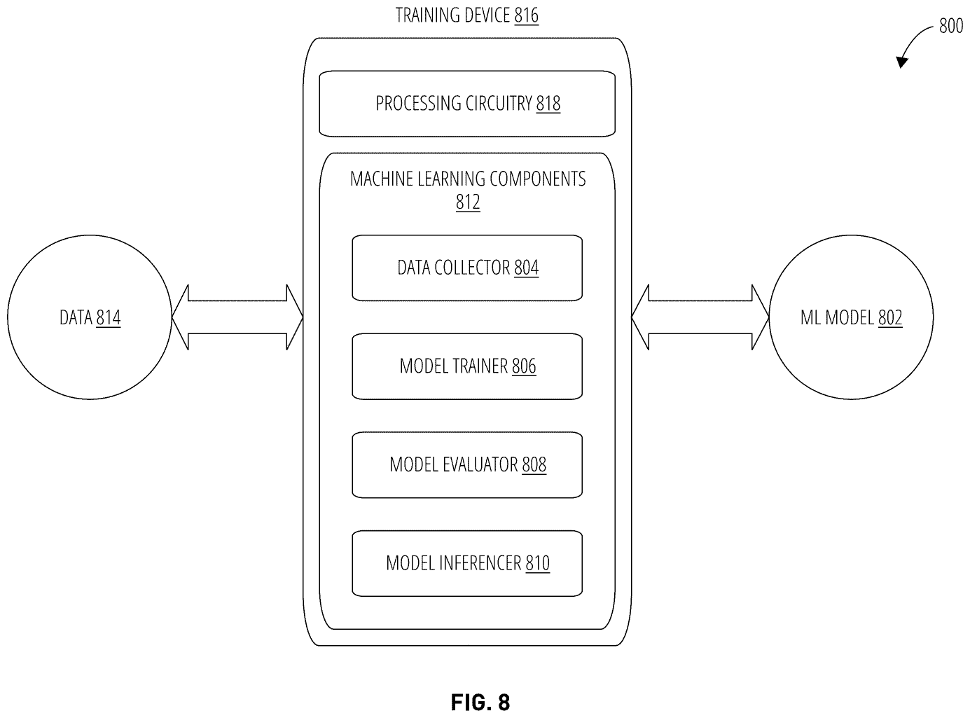

FIG. 8 illustrates an apparatus 800. The apparatus 800 depicts a training device 816 suitable to generate a trained ML model 802 for an inferencing device, such as the device 302 of the inferencing system 300. In one embodiment, the training device 816 executes various ML components 812 to generate an ML model 802, such as a control model 326, a qualifier control model 328 and/or an inverted control model 330 by performing various training, testing, and validation operations.

As depicted in FIG. 8, the training device 816 includes a processing circuitry 818 and a set of ML components 812 to support various AI/ML techniques, such as a data collector 804, a model trainer 806, a model evaluator 808 and a model inferencer 810.

In general, the data collector 804 collects data 814 from one or more data sources to use as training data for the ML model 802. The data collector 804 collects different types of data 814, such as text information, audio information, image information, video information, graphic information, and so forth. The model trainer 806 receives as input the collected data and uses a portion of the collected data as test data for an AI/ML algorithm to train the ML model 802. The model evaluator 808 evaluates and improves the trained ML model 802 using a portion of the collected data as test data to test the ML model 802. The model evaluator 808 also uses feedback information from the deployed ML model 802. The model inferencer 810 implements the trained ML model 802 to receive as input new unseen data, generate one or more inferences on the new data, and output a result such as an alert, a recommendation or other post-solution activity.

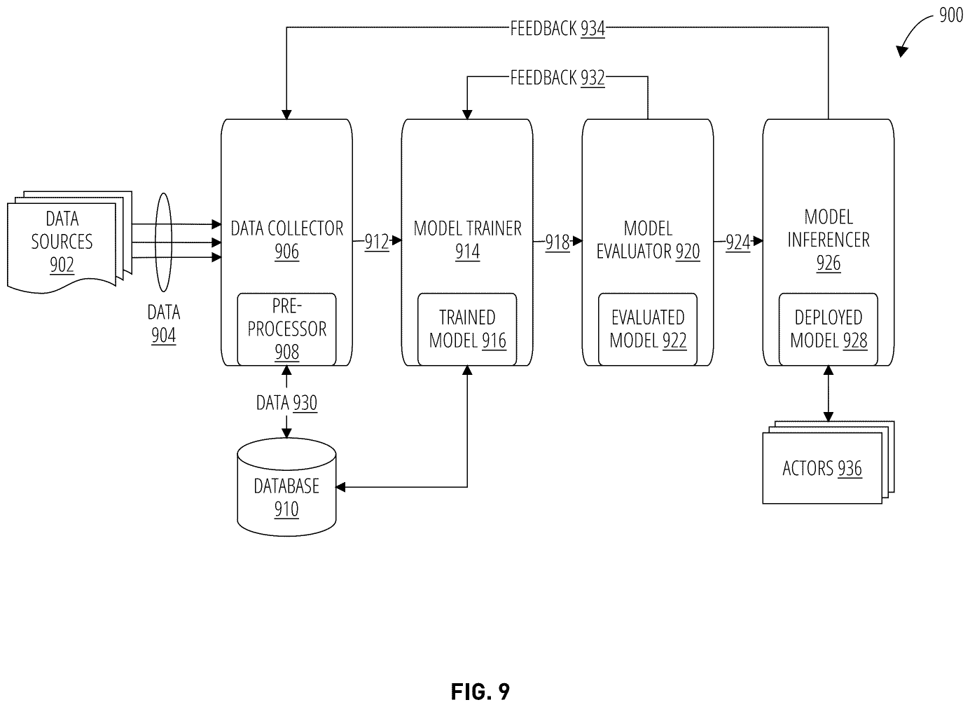

An exemplary AI/ML architecture for the ML components 812 is described in more detail with reference to FIG. 9.

FIG. 9 illustrates a training system 900. The training system 900 is an example of a system suitable for implementing various artificial intelligence (AI) techniques and/or machine learning (ML) techniques to perform various tasks. AI is a science and technology based on principles of cognitive science, computer science and other related disciplines, which deals with the creation of intelligent machines that work and react like humans. AI is used to develop systems that can perform tasks that require human intelligence such as recognizing speech, vision and making decisions. AI can be seen as the ability for a machine or computer to think and learn, rather than just following instructions. ML is a subset of AI that uses algorithms to enable machines to learn from existing data and generate insights or predictions from that data. ML algorithms are used to optimize machine performance in various tasks such as classifying, clustering and forecasting. ML algorithms are used to create ML models that can accurately predict outcomes.

In general, the training system 900 may include various machine or computer components (e.g., circuit, processor circuit, memory, network interfaces, compute platforms, input/output (I/O) devices, etc.) for an AI/ML system that are designed to work together to create a pipeline that can take in raw data, process it, train a ML model, evaluate its performance, deploy it in a production environment, and continuously monitor and maintain it.

A ML model is a mathematical construct used to predict outcomes based on a set of input data. ML models are trained using large volumes of data, and they can recognize patterns and trends in that data to make accurate predictions. The ML models are derived from different ML algorithms. The ML algorithms may comprise supervised algorithms, unsupervised algorithms, or semi-supervised algorithms.

A supervised algorithm is a type of machine learning algorithm that uses labeled data to train a model. In supervised learning, the algorithm is given a set of input data and corresponding output data, which are used to train the model to make predictions or classifications. The input data is also known as the features, and the output data is known as the target or label. The goal of a supervised algorithm is to learn the relationship between the input features and the target labels, so that it can make accurate predictions or classifications for new, unseen data. Examples of supervised learning algorithms include: (1) linear regression which is a regression algorithm used to predict continuous numeric values, such as stock prices or temperature; (2) logistic regression which is a classification algorithm used to predict binary outcomes, such as whether a customer will churn or not; (3) decision tree which is a classification algorithm used to predict categorical outcomes by creating a decision tree based on the input features; or (4) random forest which is an ensemble algorithm that combines multiple decision trees to make more accurate predictions.

An unsupervised algorithm is a type of machine learning algorithm that is used to find patterns and relationships in a dataset without the need for labeled data. Unlike supervised learning, where the algorithm is provided with labeled training data and learns to make predictions based on that data, unsupervised learning works with unlabeled data and seeks to identify underlying structures or patterns. Unsupervised learning algorithms use a variety of techniques to discover patterns in the data, such as clustering, anomaly detection, and dimensionality reduction. Clustering algorithms group similar data points together, while anomaly detection algorithms identify unusual or unexpected data points. Dimensionality reduction algorithms are used to reduce the number of features in a dataset, making it easier to analyze and visualize. Unsupervised learning has many applications, such as in data mining, pattern recognition, and recommendation systems. It is particularly useful for tasks where labeled data is scarce or difficult to obtain, and where the goal is to gain insights and understanding from the data itself rather than to make predictions based on it.

Semi-supervised learning is a type of machine learning algorithm that combines both labeled and unlabeled data to improve the accuracy of predictions or classifications. In this approach, the algorithm is trained on a small amount of labeled data and a much larger amount of unlabeled data. The main idea behind semi-supervised learning is that labeled data is often scarce and expensive to obtain, whereas unlabeled data is abundant and easy to collect. By leveraging both types of data, semi-supervised learning can achieve higher accuracy and better generalization than either supervised or unsupervised learning alone. In semi-supervised learning, the algorithm first uses the labeled data to learn the underlying structure of the problem. It then uses this knowledge to identify patterns and relationships in the unlabeled data, and to make predictions or classifications based on these patterns. Semi-supervised learning has many applications, such as in speech recognition, natural language processing, and computer vision. It is particularly useful for tasks where labeled data is expensive or time-consuming to obtain, and where the goal is to improve the accuracy of predictions or classifications by leveraging large amounts of unlabeled data.

The training system 900 may implement various types of ML algorithms including supervised algorithms, unsupervised algorithms, semi-supervised algorithms, or a combination thereof. A few examples of ML algorithms include support vector machine (SVM), random forests, naive Bayes, K-means clustering, neural networks, and so forth. A SVM is an algorithm that can be used for both classification and regression problems. It works by finding an optimal hyperplane that maximizes the margin between the two classes. Random forests is a type of decision tree algorithm that is used to make predictions based on a set of randomly selected features. Naive Bayes is a probabilistic classifier that makes predictions based on the probability of certain events occurring. K-Means Clustering is an unsupervised learning algorithm that groups data points into clusters. Neural networks is a type of machine learning algorithm that is designed to mimic the behavior of neurons in the human brain. Other examples of ML algorithms include an artificial neural network (ANN), convolutional neural network (CNN), deep learning, decision tree learning, support-vector machine, regression analysis, Bayesian networks, genetic algorithms, federated learning, distributed artificial intelligence, and various other ML algorithms.

As depicted in FIG. 9, the training system 900 includes a set of data sources 902 to source data 904 for the training system 900. Data sources 902 may comprise any device capable generating, processing, storing or managing data 904 suitable for a ML system. Examples of data sources 902 include without limitation databases, web scraping, sensors and Internet of Things (IoT) devices, image and video cameras, audio devices, text generators, publicly available databases, private databases, and many other data sources 902. The data sources 902 may be remote from the training system 900 and accessed via a network, local to the training system 900 an accessed via a network interface, or may be a combination of local and remote data sources 902.

The data sources 902 may source difference types of data 904. For instance, the data 904 may comprise structured data from relational databases, such as customer profiles, transaction histories, or product inventories. The data 904 may comprise unstructured data from websites such as customer reviews, news articles, social media posts, or product specifications. The data 904 may comprise data from temperature sensors, motion detectors, and smart home appliances. The data 904 may comprise image data from medical images, security footage, or satellite images. The data 904 may comprise audio data from speech recognition, music recognition, or call centers. The data 904 may comprise text data from emails, chat logs, customer feedback, news articles or social media posts. The data 904 may comprise publicly available datasets such as those from government agencies, academic institutions, or research organizations. These are just a few examples of the many sources of data that can be used for ML systems. It is important to note that the quality and quantity of the data is critical for the success of a machine learning project.

The data 904 can be in different formats such as structured, unstructured or semi-structured data. Structured data refers to data that is organized in a specific format or schema, such as tables or spreadsheets. Structured data has a well-defined set of rules that dictate how the data should be organized and represented, including the data types and relationships between data elements. Unstructured data refers to any data that does not have a predefined or organized format or schema. Unlike structured data, which is organized in a specific way, unstructured data can take various forms, such as text, images, audio, or video. Unstructured data can come from a variety of sources, including social media, emails, sensor data, and website content. Semi-structured data is a type of data that does not fit neatly into the traditional categories of structured and unstructured data. It has some structure but does not conform to the rigid structure of a traditional relational database. Semi-structured data is characterized by the presence of tags or metadata that provide some structure and context for the data.

The data sources 902 may be communicatively coupled to a data collector 906. The data collector 906 gathers relevant data 904 from the data sources 902. Once collected, the data collector 906 may use a pre-processor 908 to make the data 904 suitable for analysis. This involves data cleaning, transformation, and feature engineering. Data preprocessing is a critical step in ML as it directly impacts the accuracy and effectiveness of the model. The pre-processor 908 may receive the data 904 as input, process the data 904, and output pre-processed data 930 for storage in a database 910. The database 910 may comprise a hard drive, solid state storage, and/or random access memory.

The data collector 906 may be communicatively coupled to a model trainer 914. The model trainer 914 performs AI/ML model training, validation, and testing which may generate model performance metrics as part of the model testing procedure. The model trainer 914 may receive the pre-processed data 930 as input 912 or via the database 910. The model trainer 914 may implement a suitable ML algorithm to train an ML model on the pre-processed data 930. The training process involves feeding the pre-processed data 930 into a ML model to form a trained model 916. The training process adjusts its parameters until it achieves an initial level of satisfactory performance.

The model trainer 914 may be communicatively coupled to a model evaluator 920. After a ML model is trained, the trained model 916 needs to be evaluated to assess its performance. This is done using various metrics such as accuracy, precision, recall, and F1 score. The model trainer 914 may output the trained model 916, which is received as input 912. The model evaluator 920 receives the trained model 916, and it initiates an evaluation process to measure performance of the trained model 916. The evaluation process may include providing feedback 932 to the model trainer 914, so that it may re-train the trained model 916 to improve performance in an iterative manner.

The model evaluator 920 may be communicatively coupled to a model inferencer 926. The model inferencer 926 provides AI/ML model inference output (e.g., predictions or decisions). Once the ML model is trained and evaluated, it can be deployed in a production environment where it can be used to make predictions on new data. The model inferencer 926 receives the evaluated model 922 as input 924. The model inferencer 926 may use the evaluated model 922 as a deployed model 928, which is a final production ML model. The inference output of the deployed model 928 is use case specific. The model inferencer 926 may also perform model monitoring and maintenance, which involves continuously monitoring performance of the deployed model 928 in the production environment and making any necessary updates or modifications to maintain its accuracy and effectiveness. The model inferencer 926 may provide feedback 932 to the data collector 906 to train or re-train the ML model. The feedback 932 may include model performance feedback information, which may be used for monitoring and improving performance of the deployed model 928.

The model inferencer 926 may be implemented by various actors 936 in the training system 900. The actors 936 may use the deployed model 928 on new data to make inferences or predictions for a given task. The actors 936 may actually implement the model inferencer 926, or receive outputs from the model inferencer 926 in a distributed computing manner. The actors 936 may trigger actions directed to other entities or to itself. The actors 936 may provide feedback 934 to the data collector 906 via the model inferencer 926. The feedback 934 may comprise data needed to derive training data, inference data or to monitor the performance of the AI/ML model and its impact to the network through updating of key performance indicators (KPIs) and performance counters.

The training system 900 may be applicable to various use cases and solutions for AI/ML tasks, such as the inferencing system 300 and/or training system 400. Other use cases and solutions for AI/ML are possible as well, and embodiments are not limited in this context.

FIG. 10 illustrates an embodiment of an artificial neural network 1000. Neural networks, also known as artificial neural networks (ANNs) or simulated neural networks (SNNs), are a subset of machine learning and are at the core of deep learning algorithms. Their name and structure are inspired by the human brain, mimicking the way that biological neurons signal to one another.

Artificial neural network 1000 comprises multiple node layers, containing an input layer 1032, one or more hidden layers 1034, and an output layer 1036. Each layer comprises one or more nodes. As depicted in FIG. 10, for example, the input layer 1032 has input node 1008 and input node 1010. The artificial neural network 1000 has two hidden layers 1034, with a first hidden layer having neuron 1012, neuron 1014, neuron 1016 and neuron 1018, and a second hidden layer having neuron 1020, neuron 1022, neuron 1024 and neuron 1026. The artificial neural network 1000 has an output layer 1036 with output node 1028 and output node 1030. Each node or neuron comprises a processing element (PE), or artificial neuron, that connects to another and has an associated weight and threshold. If the output of any individual node is above the specified threshold value, that node is activated, sending data to the next layer of the network. Otherwise, no data is passed along to the next layer of the network.

In general, artificial neural network 1000 relies on training data 1002 to learn and improve accuracy over time. However, once the artificial neural network 1000 is fine-tuned for accuracy, and tested on testing data 1004, the artificial neural network 1000 is ready to classify and cluster new data 1006 at a high velocity. Tasks in speech recognition, image recognition, or calculating continuous values can take minutes versus hours when compared to the manual identification by human experts.

The artificial neural network 1000 is a linear regression model, composed of input data, weights, a bias (or threshold), and an output. Once an input layer 1032 is determined, a set of weights 1038 are assigned. The weights 1038 help determine the importance of any given variable, with larger ones contributing more significantly to the output compared to other inputs. All inputs are then multiplied by their respective weights and then summed. Afterward, the output is passed through an activation function, which determines the output. If that output exceeds a given threshold, it “fires” (or activates) the node, passing data to the next layer in the network. This results in the output of one node becoming in the input of the next node. The process of passing data from one layer to the next layer defines the artificial neural network 1000 as a feedforward network.

In one embodiment, the artificial neural network 1000 leverages sigmoid neurons, which are distinguished by having values between 0 and 1. Since the artificial neural network 1000 behaves similarly to a decision tree, cascading data from one node to another, having x values between 0 and 1 will reduce the impact of any given change of a single variable on the output of any given node, and subsequently, the output of the artificial neural network 1000.

The artificial neural network 1000 has many practical use cases, like image recognition, speech recognition, text recognition or classification. The artificial neural network 1000 leverages supervised learning, or labeled datasets, to train the algorithm. As the model is trained, its accuracy is measured using a cost (or loss) function. This is also commonly referred to as the mean squared error (MSE).

Ultimately, the goal is to minimize the cost function to ensure correctness of fit for any given observation. As the model adjusts its weights and bias, it uses the cost function and reinforcement learning to reach the point of convergence, or the local minimum. The process in which the algorithm adjusts its weights is through gradient descent, allowing the model to determine the direction to take to reduce errors (or minimize the cost function). With each training example, the parameters 1040 of the model adjust to gradually converge at the minimum.

In one embodiment, the artificial neural network 1000 is feedforward, meaning it flows in one direction only, from input to output. In one embodiment, the artificial neural network 1000 uses backpropagation. Backpropagation is when the artificial neural network 1000 moves in the opposite direction from output to input. Backpropagation allows calculation and attribution of errors associated with each neuron, thereby allowing adjustment to fit the parameters 1040 of the ML model 802 appropriately.

The artificial neural network 1000 is implemented as different neural networks depending on a given task. Neural networks are classified into different types, which are used for different purposes. In one embodiment, the artificial neural network 1000 is implemented as a feedforward neural network, or multi-layer perceptrons (MLPs), comprised of an input layer 1032, hidden layers 1034, and an output layer 1036. While these neural networks are also commonly referred to as MLPs, they are actually comprised of sigmoid neurons, not perceptrons, as most real-world problems are nonlinear. Trained data 904 usually is fed into these models to train them, and they are the foundation for computer vision, natural language processing, and other neural networks. In one embodiment, the artificial neural network 1000 is implemented as a convolutional neural network (CNN). A CNN is similar to feedforward networks, but usually utilized for image recognition, pattern recognition, and/or computer vision. These networks harness principles from linear algebra, particularly matrix multiplication, to identify patterns within an image. In one embodiment, the artificial neural network 1000 is implemented as a recurrent neural network (RNN). A RNN is identified by feedback loops. The RNN learning algorithms are primarily leveraged when using time-series data to make predictions about future outcomes, such as stock market predictions or sales forecasting. The artificial neural network 1000 is implemented as any type of neural network suitable for a given operational task of inferencing system 300, and the MLP, CNN, and RNN are merely a few examples. Embodiments are not limited in this context.

The artificial neural network 1000 includes a set of associated parameters 1040. There are a number of different parameters that must be decided upon when designing a neural network. Among these parameters are the number of layers, the number of neurons per layer, the number of training iterations, and so forth. Some of the more important parameters in terms of training and network capacity are a number of hidden neurons parameter, a learning rate parameter, a momentum parameter, a training type parameter, an Epoch parameter, a minimum error parameter, and so forth.

In some cases, the artificial neural network 1000 is implemented as a deep learning neural network. The term deep learning neural network refers to a depth of layers in a given neural network. A neural network that has more than three layers—which would be inclusive of the inputs and the output—can be considered a deep learning algorithm. A neural network that only has two or three layers, however, may be referred to as a basic neural network. A deep learning neural network may tune and optimize one or more hyperparameters 1042. A hyperparameter is a parameter whose values are set before starting the model training process. Deep learning models, including convolutional neural network (CNN) and recurrent neural network (RNN) models can have anywhere from a few hyperparameters to a few hundred hyperparameters. The values specified for these hyperparameters impacts the model learning rate and other regulations during the training process as well as final model performance. A deep learning neural network uses hyperparameter optimization algorithms to automatically optimize models. The algorithms used include Random Search, Tree-structured Parzen Estimator (TPE) and Bayesian optimization based on the Gaussian process. These algorithms are combined with a distributed training engine for quick parallel searching of the optimal hyperparameter values.

FIG. 11 illustrates a set of activation functions 1100 for the ML models 324 and ML model 802. As previously discussed, in one embodiment, the inverted control model 330 comprises a regression neural network that includes one input layer, one or more hidden layers, and an output layer, where each neuron in the one or more hidden layers performs computations on input data using an activation function. The set of activation functions 1100 include a Rectified Linear Unit (ReLU) function, a leaky ReLU function, a Tanh function, a Binary Step function, a linear function, a Scaled Exponential Linear Unit (SELU) function, an Exponential Linear Unit (ELU) function, a Sigmoid or Logistic function, and a Parametric ReLU function. There are other activation functions suitable for use with the ML models 324 and the ML model 802 as well. Embodiments are not limited to a particular activation function.

An activation function for a neuron in a neural network is a mathematical function that determines the output of that neuron given its input. It adds non-linearity to the network, allowing it to learn and model complex relationships between inputs and outputs. There are several commonly used activation functions in neural networks. One example is a sigmoid. The sigmoid function squashes the input into a range between 0 and 1. It is defined as f(x)=1/(1+exp(−x)). It is widely used in the past but has fallen out of favor due to gradient saturation issues. Another example is a Rectified Linear Unit (ReLU) function. The rectified linear unit is one of the most widely used activation functions. It is defined as f(x)=max(0, x). ReLU introduces non-linearity by outputting the input directly if it is positive, and zero otherwise. ReLU helps to address the vanishing gradient problem and is computationally efficient. Another example is a leaky ReLU. The leaky ReLU function is a variant of the ReLU function. It allows small negative values when the input is below 0, preventing dead neurons. It is defined as f(x)=max(0.01x, x), where 0.01 is the small slope for negative values. Yet another example is softmax. The softmax function is often used in the output layer of a neural network for multi-class classification problems. It takes a vector of real values as input and transforms them into a probability distribution. Each output represents the probability of the input belonging to a particular class. These are just a few examples of activation functions commonly used in neural networks.

In one embodiment, the ML models 324 and the ML model 802 uses a linear activation function to generate a continuous output value. The linear activation function includes a ReLU function, a leaky ReLU function, or a parametric ReLU function. Embodiments are not limited to these particular activation functions.

Operations for the disclosed embodiments may be further described with reference to the following figures. Some of the figures may include a logic flow. Although such figures presented herein may include a particular logic flow, it can be appreciated that the logic flow merely provides an example of how the general functionality as described herein can be implemented. Further, a given logic flow does not necessarily have to be executed in the order presented unless otherwise indicated. Moreover, not all acts illustrated in a logic flow may be required in some embodiments. In addition, the given logic flow may be implemented by a hardware element, a software element executed by a processor, or any combination thereof. The embodiments are not limited in this context.

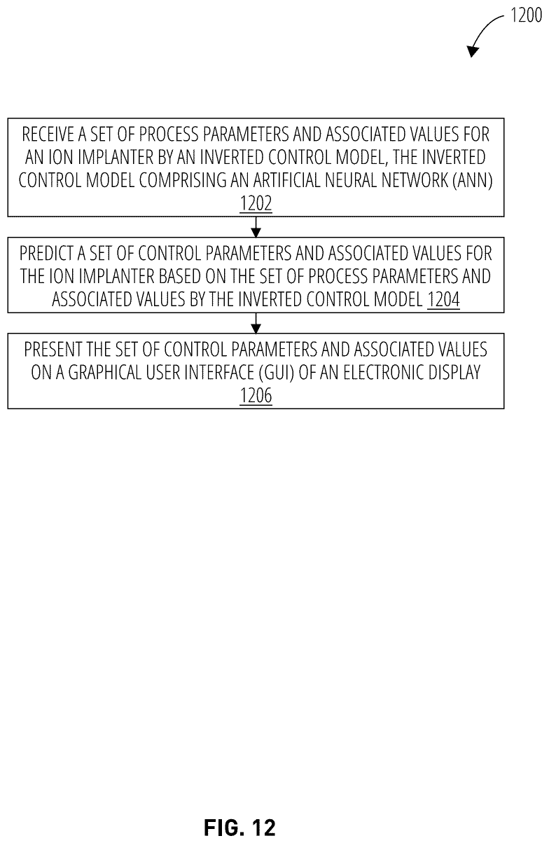

FIG. 12 illustrates an embodiment of a logic flow 1200. The logic flow 1200 may be representative of some or all of the operations executed by one or more embodiments described herein. For example, the logic flow 1200 may include some or all of the operations performed by devices or entities within the inferencing system 300, the training system 400, the device 302, or the training device 816. More particularly, the logic flow 1200 illustrates an example where the device 302 performs inferencing operations for the ML models 324.

In block 1202, logic flow 1200 receives a set of process parameters and associated values for an ion implanter by an inverted control model, the inverted control model comprising an artificial neural network (ANN). In block 1204, logic flow 1200 predicts a set of control parameters and associated values for the ion implanter based on the set of process parameters and associated values by the inverted control model. In block 1206, logic flow 1200 presents the set of control parameters and associated values on a graphical user interface (GUI) of an electronic display.

By way of example, with reference to the device 302, the settings manager 320 receives a set of process parameters 336 and associated values for an ion implanter 102 by an inverted control model 330. The inverted control model 330 comprises an artificial neural network (ANN), such as a feedforward neural network (FNN). The inverted control model 330 predicts a set of control parameters 334 and associated values for the ion implanter 102 based on the set of process parameters 336 and associated values. The settings manager 320 then presents the set of control parameters 334 and associated values on a GUI 342 of an electronic display 344 communicatively coupled to the device 302.

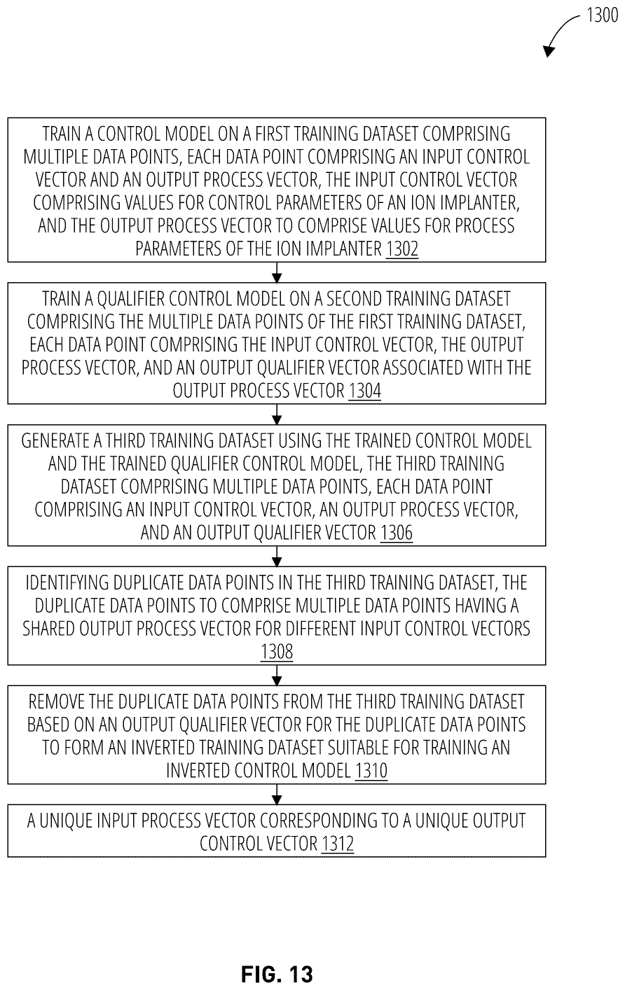

FIG. 13 illustrates an embodiment of a logic flow 1300. The logic flow 1300 may be representative of some or all of the operations executed by one or more embodiments described herein. For example, the logic flow 1300 may include some or all of the operations performed by devices or entities within the inferencing system 300, the training system 400, the device 302, or the training device 816. More particularly, the logic flow 1300 illustrates an example where the device 302 or the training device 816 performs training operations for the ML models 324 using the training system 400 or the training system 900.

In block 1302, logic flow 1300 trains a control model on a first training dataset comprising multiple data points, each data point comprising an input control vector and an output process vector, the input control vector comprising values for control parameters of an ion implanter, and the output process vector to comprise values for process parameters of the ion implanter. In block 1304, logic flow 1300 trains a qualifier control model on a second training dataset comprising the multiple data points of the first training dataset, each data point comprising the input control vector, the output process vector, and an output qualifier vector associated with the output process vector. In block 1306, logic flow 1300 generates a third training dataset using the trained control model and the trained qualifier control model, the third training dataset comprising multiple data points, each data point comprising an input control vector, an output process vector, and an output qualifier vector. In block 1308, logic flow 1300 identifying duplicate data points in the third training dataset, the duplicate data points to comprise multiple data points having a shared output process vector for different input control vectors. In block 1310, logic flow 1300 removes the duplicate data points from the third training dataset based on an output qualifier vector for the duplicate data points to form an inverted training dataset suitable for training an inverted control model. In block 1312, logic flow 1300 a unique input process vector corresponding to a unique output control vector.

By way of example, with reference to training system 400, the model manager 322 trains a control model 326 on a first training dataset 402 that includes multiple data points. Each data point includes an input control vector and an output process vector. The input control vector includes values for control parameters 334 of an ion implanter 102. The output process vector comprises values for process parameters 336 of the ion implanter 102. The model manager 322 trains a qualifier control model 328 on a second training dataset 408 that includes the multiple data points of the first training dataset 402. Each data point includes the input control vector, the output process vector, and an output qualifier vector associated with the output process vector. The model manager 322 generates a third training dataset, such as an interim training dataset 414, using the trained control model 326 and the trained qualifier control model 328. The interim training dataset 414 includes multiple data points. Each data point includes an input control vector, an output process vector, and an output qualifier vector. A data de-duplicator 416 identifies duplicate data points 418 in the interim training dataset 414. The duplicate data points 418 comprise multiple data points having a shared output process vector for different input control vectors. The data de-duplicator 416 removes the duplicate data points 418 from the interim training dataset 414 based on an output qualifier vector for the duplicate data points 418. The data de-duplicator 416 then stores the interim training dataset 414 as an inverted training dataset 420. The model manager 322 then trains an inverted control model 330 on the inverted training dataset 420 that includes multiple data points, where each data point includes a unique input process vector corresponding to a unique output control vector, and therefore represents a function.

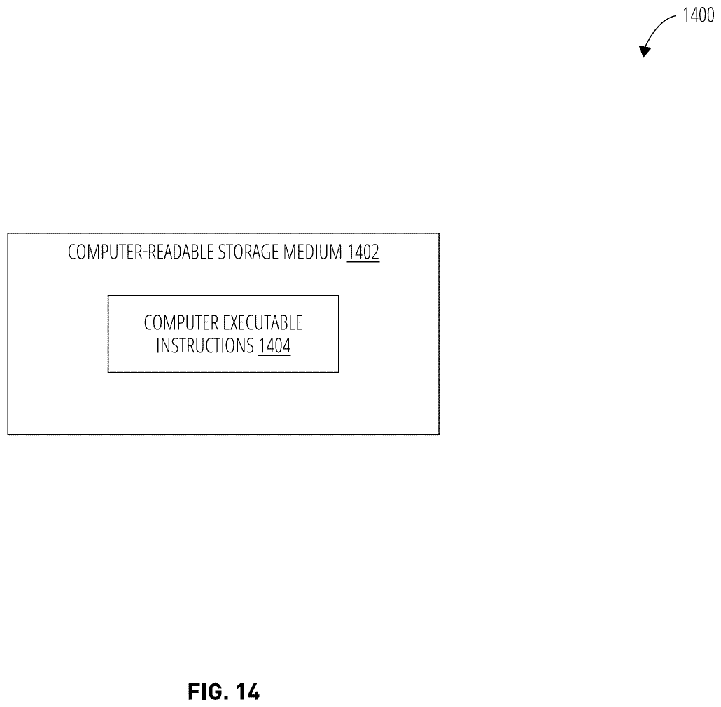

FIG. 14 illustrates an apparatus 1400. Apparatus 1400 may comprise any non-transitory computer-readable storage medium 1402 or machine-readable storage medium, such as an optical, magnetic or semiconductor storage medium. In various embodiments, apparatus 1400 may comprise an article of manufacture or a product. In some embodiments, the computer-readable storage medium 1402 may store computer executable instructions with which circuitry can execute. For example, computer executable instructions 1404 can include instructions to implement operations described with respect to any logic flows described herein. Examples of computer-readable storage medium 1402 or machine-readable storage medium may include any tangible media capable of storing electronic data, including volatile memory or non-volatile memory, removable or non-removable memory, erasable or non-erasable memory, writeable or re-writeable memory, and so forth. Examples of computer executable instructions 1404 may include any suitable type of code, such as source code, compiled code, interpreted code, executable code, static code, dynamic code, object-oriented code, visual code, and the like.

FIG. 15 illustrates an embodiment of a computing architecture 1500. Computing architecture 1500 is a computer system with multiple processor cores such as a distributed computing system, supercomputer, high-performance computing system, computing cluster, mainframe computer, mini-computer, client-server system, personal computer (PC), workstation, server, portable computer, laptop computer, tablet computer, handheld device such as a personal digital assistant (PDA), or other device for processing, displaying, or transmitting information. Similar embodiments may comprise, e.g., entertainment devices such as a portable music player or a portable video player, a smart phone or other cellular phone, a telephone, a digital video camera, a digital still camera, an external storage device, or the like. Further embodiments implement larger scale server configurations. In other embodiments, the computing architecture 1500 may have a single processor with one core or more than one processor. Note that the term “processor” refers to a processor with a single core or a processor package with multiple processor cores. In at least one embodiment, the computing architecture 1500 is representative of the components of the inferencing system 300. More generally, the computing architecture 1500 is configured to implement all logic, systems, logic flows, methods, apparatuses, and functionality described herein with reference to previous figures.

As used in this application, the terms “system” and “component” and “module” are intended to refer to a computer-related entity, either hardware, a combination of hardware and software, software, or software in execution, examples of which are provided by the exemplary computing architecture 1500. For example, a component can be, but is not limited to being, a process running on a processor, a processor, a hard disk drive, multiple storage drives (of optical and/or magnetic storage medium), an object, an executable, a thread of execution, a program, and/or a computer. By way of illustration, both an application running on a server and the server can be a component. One or more components can reside within a process and/or thread of execution, and a component can be localized on one computer and/or distributed between two or more computers. Further, components may be communicatively coupled to each other by various types of communications media to coordinate operations. The coordination may involve the uni-directional or bi-directional exchange of information. For instance, the components may communicate information in the form of signals communicated over the communications media. The information can be implemented as signals allocated to various signal lines. In such allocations, each message is a signal. Further embodiments, however, may alternatively employ data messages. Such data messages may be sent across various connections. Exemplary connections include parallel interfaces, serial interfaces, and bus interfaces.

As shown in FIG. 15, computing architecture 1500 comprises a system-on-chip (SoC) 1502 for mounting platform components. System-on-chip (SoC) 1502 is a point-to-point (P2P) interconnect platform that includes a first processor 1504 and a second processor 1506 coupled via a point-to-point interconnect 1570 such as an Ultra Path Interconnect (UPI). In other embodiments, the computing architecture 1500 may be of another bus architecture, such as a multi-drop bus. Furthermore, each of processor 1504 and processor 1506 may be processor packages with multiple processor cores including core(s) 1508 and core(s) 1510, respectively. While the computing architecture 1500 is an example of a two-socket (2S) platform, other embodiments may include more than two sockets or one socket. For example, some embodiments may include a four-socket (4S) platform or an eight-socket (8S) platform. Each socket is a mount for a processor and may have a socket identifier. Note that the term platform may refers to a motherboard with certain components mounted such as the processor 1504 and chipset 1532. Some platforms may include additional components and some platforms may only include sockets to mount the processors and/or the chipset. Furthermore, some platforms may not have sockets (e.g. SoC, or the like). Although depicted as a SoC 1502, one or more of the components of the SoC 1502 may also be included in a single die package, a multi-chip module (MCM), a multi-die package, a chiplet, a bridge, and/or an interposer. Therefore, embodiments are not limited to a SoC.

The processor 1504 and processor 1506 can be any of various commercially available processors, including without limitation an Intel® Celeron®, Core®, Core (2) Duo®, Itanium®, Pentium®, Xeon®, and XScale® processors; AMD® Athlon®, Duron® and Opteron® processors; ARM® application, embedded and secure processors; IBM® and Motorola® DragonBall® and PowerPC® processors; IBM and Sony® Cell processors; and similar processors. Dual microprocessors, multi-core processors, and other multi-processor architectures may also be employed as the processor 1504 and/or processor 1506. Additionally, the processor 1504 need not be identical to processor 1506.

Processor 1504 includes an integrated memory controller (IMC) 1520 and point-to-point (P2P) interface 1524 and P2P interface 1528. Similarly, the processor 1506 includes an IMC 1522 as well as P2P interface 1526 and P2P interface 1530. IMC 1520 and IMC 1522 couple the processor 1504 and processor 1506, respectively, to respective memories (e.g., memory 1516 and memory 1518). Memory 1516 and memory 1518 may be portions of the main memory (e.g., a dynamic random-access memory (DRAM)) for the platform such as double data rate type 4 (DDR4) or type 5 (DDR5) synchronous DRAM (SDRAM). In the present embodiment, the memory 1516 and the memory 1518 locally attach to the respective processors (i.e., processor 1504 and processor 1506). In other embodiments, the main memory may couple with the processors via a bus and shared memory hub. Processor 1504 includes registers 1512 and processor 1506 includes registers 1514.

Computing architecture 1500 includes chipset 1532 coupled to processor 1504 and processor 1506. Furthermore, chipset 1532 can be coupled to storage device 1550, for example, via an interface (I/F) 1538. The I/F 1538 may be, for example, a Peripheral Component Interconnect-enhanced (PCIe) interface, a Compute Express Link® (CXL) interface, or a Universal Chiplet Interconnect Express (UCIe) interface. Storage device 1550 can store instructions executable by circuitry of computing architecture 1500 (e.g., processor 1504, processor 1506, GPU 1548, accelerator 1554, vision processing unit 1556, or the like). For example, storage device 1550 can store instructions for device 302, devices 312, devices 316, or the like.

Processor 1504 couples to the chipset 1532 via P2P interface 1528 and P2P 1534 while processor 1506 couples to the chipset 1532 via P2P interface 1530 and P2P 1536. Direct media interface (DMI) 1576 and DMI 1578 may couple the P2P interface 1528 and the P2P 1534 and the P2P interface 1530 and P2P 1536, respectively. DMI 1576 and DMI 1578 may be a high-speed interconnect that facilitates, e.g., eight Giga Transfers per second (GT/s) such as DMI 3.0. In other embodiments, the processor 1504 and processor 1506 may interconnect via a bus.

The chipset 1532 may comprise a controller hub such as a platform controller hub (PCH). The chipset 1532 may include a system clock to perform clocking functions and include interfaces for an I/O bus such as a universal serial bus (USB), peripheral component interconnects (PCIs), CXL interconnects, UCIe interconnects, interface serial peripheral interconnects (SPIs), integrated interconnects (I2Cs), and the like, to facilitate connection of peripheral devices on the platform. In other embodiments, the chipset 1532 may comprise more than one controller hub such as a chipset with a memory controller hub, a graphics controller hub, and an input/output (I/O) controller hub.

In the depicted example, chipset 1532 couples with a trusted platform module (TPM) 1544 and UEFI, BIOS, FLASH circuitry 1546 via I/F 1542. The TPM 1544 is a dedicated microcontroller designed to secure hardware by integrating cryptographic keys into devices. The UEFI, BIOS, FLASH circuitry 1546 may provide pre-boot code.

Furthermore, chipset 1532 includes the I/F 1538 to couple chipset 1532 with a high-performance graphics engine, such as, graphics processing circuitry or a graphics processing unit (GPU) 1548. In other embodiments, the computing architecture 1500 may include a flexible display interface (FDI) (not shown) between the processor 1504 and/or the processor 1506 and the chipset 1532. The FDI interconnects a graphics processor core in one or more of processor 1504 and/or processor 1506 with the chipset 1532.

The computing architecture 1500 is operable to communicate with wired and wireless devices or entities via the network interface (NIC) 180 using the IEEE 802 family of standards, such as wireless devices operatively disposed in wireless communication (e.g., IEEE 802.11 over-the-air modulation techniques). This includes at least Wi-Fi (or Wireless Fidelity), WiMax, and Bluetooth™ wireless technologies, 3G, 4G, LTE wireless technologies, among others. Thus, the communication can be a predefined structure as with a conventional network or simply an ad hoc communication between at least two devices. Wi-Fi networks use radio technologies called IEEE 802.11x (a, b, g, n, ac, ax, etc.) to provide secure, reliable, fast wireless connectivity. A Wi-Fi network can be used to connect computers to each other, to the Internet, and to wired networks (which use IEEE 802.3-related media and functions).

Additionally, accelerator 1554 and/or vision processing unit 1556 can be coupled to chipset 1532 via I/F 1538. The accelerator 1554 is representative of any type of accelerator device (e.g., a data streaming accelerator, cryptographic accelerator, cryptographic co-processor, an offload engine, etc.). One example of an accelerator 1554 is the Intel® Data Streaming Accelerator (DSA). The accelerator 1554 may be a device including circuitry to accelerate copy operations, data encryption, hash value computation, data comparison operations (including comparison of data in memory 1516 and/or memory 1518), and/or data compression. For example, the accelerator 1554 may be a USB device, PCI device, PCIe device, CXL device, UCIe device, and/or an SPI device. The accelerator 1554 can also include circuitry arranged to execute machine learning (ML) related operations (e.g., training, inference, etc.) for ML models. Generally, the accelerator 1554 may be specially designed to perform computationally intensive operations, such as hash value computations, comparison operations, cryptographic operations, and/or compression operations, in a manner that is more efficient than when performed by the processor 1504 or processor 1506. Because the load of the computing architecture 1500 may include hash value computations, comparison operations, cryptographic operations, and/or compression operations, the accelerator 1554 can greatly increase performance of the computing architecture 1500 for these operations.

The accelerator 1554 may include one or more dedicated work queues and one or more shared work queues (each not pictured). Generally, a shared work queue is configured to store descriptors submitted by multiple software entities. The software may be any type of executable code, such as a process, a thread, an application, a virtual machine, a container, a microservice, etc., that share the accelerator 1554. For example, the accelerator 1554 may be shared according to the Single Root I/O virtualization (SR-IOV) architecture and/or the Scalable I/O virtualization (S-IOV) architecture. Embodiments are not limited in these contexts. In some embodiments, software uses an instruction to atomically submit the descriptor to the accelerator 1554 via a non-posted write (e.g., a deferred memory write (DMWr)). One example of an instruction that atomically submits a work descriptor to the shared work queue of the accelerator 1554 is the ENQCMD command or instruction (which may be referred to as “ENQCMD” herein) supported by the Intel® Instruction Set Architecture (ISA). However, any instruction having a descriptor that includes indications of the operation to be performed, a source virtual address for the descriptor, a destination virtual address for a device-specific register of the shared work queue, virtual addresses of parameters, a virtual address of a completion record, and an identifier of an address space of the submitting process is representative of an instruction that atomically submits a work descriptor to the shared work queue of the accelerator 1554. The dedicated work queue may accept job submissions via commands such as the movdir64b instruction.

Various I/O devices 1560 and display 1552 couple to the bus 1572, along with a bus bridge 1558 which couples the bus 1572 to a second bus 1574 and an I/F 1540 that connects the bus 1572 with the chipset 1532. In one embodiment, the second bus 1574 may be a low pin count (LPC) bus. Various devices may couple to the second bus 1574 including, for example, a keyboard 1562, a mouse 1564 and communication devices 1566.

Furthermore, an audio I/O 1568 may couple to second bus 1574. Many of the I/O devices 1560 and communication devices 1566 may reside on the system-on-chip (SoC) 1502 while the keyboard 1562 and the mouse 1564 may be add-on peripherals. In other embodiments, some or all the I/O devices 1560 and communication devices 1566 are add-on peripherals and do not reside on the system-on-chip (SoC) 1502.

FIG. 16 illustrates a block diagram of an exemplary communications architecture 1600 suitable for implementing various embodiments as previously described. The communications architecture 1600 includes various common communications elements, such as a transmitter, receiver, transceiver, radio, network interface, baseband processor, antenna, amplifiers, filters, power supplies, and so forth. The embodiments, however, are not limited to implementation by the communications architecture 1600.

As shown in FIG. 16, the communications architecture 1600 includes one or more clients 1602 and servers 1604. The clients 1602 may implement a client version of the device 302, for example. The servers 1604 may implement a server version of the device 302, for example. The clients 1602 and the servers 1604 are operatively connected to one or more respective client data stores 1608 and server data stores 1610 that can be employed to store information local to the respective clients 1602 and servers 1604, such as cookies and/or associated contextual information.

The clients 1602 and the servers 1604 may communicate information between each other using a communication framework 1606. The communications communication framework 1606 may implement any well-known communications techniques and protocols. The communications communication framework 1606 may be implemented as a packet-switched network (e.g., public networks such as the Internet, private networks such as an enterprise intranet, and so forth), a circuit-switched network (e.g., the public switched telephone network), or a combination of a packet-switched network and a circuit-switched network (with suitable gateways and translators).

(117) The communication framework 1606 may implement various network interfaces arranged to accept, communicate, and connect to a communications network. A network interface may be regarded as a specialized form of an input output interface. Network interfaces may employ connection protocols including without limitation direct connect, Ethernet (e.g., thick, thin, twisted pair 10/300/1000 Base T, and the like), token ring, wireless network interfaces, cellular network interfaces, IEEE 802.11 network interfaces, IEEE 802.16 network interfaces, IEEE 802.20 network interfaces, and the like. Further, multiple network interfaces may be used to engage with various communications network types. For example, multiple network interfaces may be employed to allow for the communication over broadcast, multicast, and unicast networks. Should processing requirements dictate a greater amount speed and capacity, distributed network controller architectures may similarly be employed to pool, load balance, and otherwise increase the communicative bandwidth required by clients 1602 and the servers 1604. A communications network may be any one and the combination of wired and/or wireless networks including without limitation a direct interconnection, a secured custom connection, a private network (e.g., an enterprise intranet), a public network (e.g., the Internet), a Personal Area Network (PAN), a Local Area Network (LAN), a Metropolitan Area Network (MAN), an Operating Missions as Nodes on the Internet (OMNI), a Wide Area Network (WAN), a wireless network, a cellular network, and other communications networks.

The components and features of the devices described above may be implemented using any combination of discrete circuitry, application specific integrated circuits (ASICs), logic gates and/or single chip architectures. Further, the features of the devices may be implemented using microcontrollers, programmable logic arrays and/or microprocessors or any combination of the foregoing where suitably appropriate. It is noted that hardware, firmware and/or software elements may be collectively or individually referred to herein as “logic” or “circuit.”

It will be appreciated that the exemplary devices shown in the block diagrams described above may represent one functionally descriptive example of many potential implementations. Accordingly, division, omission or inclusion of block functions depicted in the accompanying figures does not infer that the hardware components, circuits, software and/or elements for implementing these functions would necessarily be divided, omitted, or included in embodiments.

At least one computer-readable storage medium may include instructions that, when executed, cause a system to perform any of the computer-implemented methods described herein.

Some embodiments may be described using the expression “one embodiment” or “an embodiment” along with their derivatives. These terms mean that a particular feature, structure, or characteristic described in connection with the embodiment is included in at least one embodiment. The appearances of the phrase “in one embodiment” in various places in the specification are not necessarily all referring to the same embodiment. Moreover, unless otherwise noted the features described above are recognized to be usable together in any combination. Thus, any features discussed separately may be employed in combination with each other unless it is noted that the features are incompatible with each other.

With general reference to notations and nomenclature used herein, the detailed descriptions herein may be presented in terms of program procedures executed on a computer or network of computers. These procedural descriptions and representations are used by those skilled in the art to most effectively convey the substance of their work to others skilled in the art.

A procedure is here, and generally, conceived to be a self-consistent sequence of operations leading to a desired result. These operations are those requiring physical manipulations of physical quantities. Usually, though not necessarily, these quantities take the form of electrical, magnetic or optical signals capable of being stored, transferred, combined, compared, and otherwise manipulated. It proves convenient at times, principally for reasons of common usage, to refer to these signals as bits, values, elements, symbols, characters, terms, numbers, or the like. It should be noted, however, that all of these and similar terms are to be associated with the appropriate physical quantities and are merely convenient labels applied to those quantities.

Further, the manipulations performed are often referred to in terms, such as adding or comparing, which are commonly associated with mental operations performed by a human operator. No such capability of a human operator is necessary, or desirable in most cases, in any of the operations described herein, which form part of one or more embodiments. Rather, the operations are machine operations. Useful machines for performing operations of various embodiments include general purpose digital computers or similar devices.

Some embodiments may be described using the expression “coupled” and “connected” along with their derivatives. These terms are not necessarily intended as synonyms for each other. For example, some embodiments may be described using the terms “connected” and/or “coupled” to indicate that two or more elements are in direct physical or electrical contact with each other. The term “coupled,” however, may also mean that two or more elements are not in direct contact with each other, but yet still co-operate or interact with each other.

Various embodiments also relate to apparatus or systems for performing these operations. This apparatus may be specially constructed for the required purpose or it may comprise a general purpose computer as selectively activated or reconfigured by a computer program stored in the computer. The procedures presented herein are not inherently related to a particular computer or other apparatus. Various general purpose machines may be used with programs written in accordance with the teachings herein, or it may prove convenient to construct more specialized apparatus to perform the required method steps. The required structure for a variety of these machines will appear from the description given.

What has been described above includes examples of the disclosed architecture. It is, of course, not possible to describe every conceivable combination of components and/or methodologies, but one of ordinary skill in the art may recognize that many further combinations and permutations are possible. Accordingly, the novel architecture is intended to embrace all such alterations, modifications and variations that fall within the spirit and scope of the appended claims.

The various elements of the devices as previously described with reference to FIGS. 1-15 may include various hardware elements, software elements, or a combination of both. Examples of hardware elements may include devices, logic devices, components, processors, microprocessors, circuits, processors, circuit elements (e.g., transistors, resistors, capacitors, inductors, and so forth), integrated circuits, application specific integrated circuits (ASIC), programmable logic devices (PLD), digital signal processors (DSP), field programmable gate array (FPGA), memory units, logic gates, registers, semiconductor device, chips, microchips, chip sets, and so forth. Examples of software elements may include software components, programs, applications, computer programs, application programs, system programs, software development programs, machine programs, operating system software, middleware, firmware, software modules, routines, subroutines, functions, methods, procedures, software interfaces, application program interfaces (API), instruction sets, computing code, computer code, code segments, computer code segments, words, values, symbols, or any combination thereof. However, determining whether an embodiment is implemented using hardware elements and/or software elements may vary in accordance with any number of factors, such as desired computational rate, power levels, heat tolerances, processing cycle budget, input data rates, output data rates, memory resources, data bus speeds and other design or performance constraints, as desired for a given implementation.

One or more aspects of at least one embodiment may be implemented by representative instructions stored on a machine-readable medium which represents various logic within the processor, which when read by a machine causes the machine to fabricate logic to perform the techniques described herein. Such representations, known as “IP cores” may be stored on a tangible, machine readable medium and supplied to various customers or manufacturing facilities to load into the fabrication machines that make the logic or processor. Some embodiments may be implemented, for example, using a machine-readable medium or article which may store an instruction or a set of instructions that, if executed by a machine, may cause the machine to perform a method and/or operations in accordance with the embodiments. Such a machine may include, for example, any suitable processing platform, computing platform, computing device, processing device, computing system, processing system, computer, processor, or the like, and may be implemented using any suitable combination of hardware and/or software. The machine-readable medium or article may include, for example, any suitable type of memory unit, memory device, memory article, memory medium, storage device, storage article, storage medium and/or storage unit, for example, memory, removable or non-removable media, erasable or non-erasable media, writeable or re-writeable media, digital or analog media, hard disk, floppy disk, Compact Disk Read Only Memory (CD-ROM), Compact Disk Recordable (CD-R), Compact Disk Rewriteable (CD-RW), optical disk, magnetic media, magneto-optical media, removable memory cards or disks, various types of Digital Versatile Disk (DVD), a tape, a cassette, or the like. The instructions may include any suitable type of code, such as source code, compiled code, interpreted code, executable code, static code, dynamic code, encrypted code, and the like, implemented using any suitable high-level, low-level, object-oriented, visual, compiled and/or interpreted programming language.

It will be appreciated that the exemplary devices shown in the block diagrams described above may represent one functionally descriptive example of many potential implementations. Accordingly, division, omission or inclusion of block functions depicted in the accompanying figures does not infer that the hardware components, circuits, software and/or elements for implementing these functions would necessarily be divided, omitted, or included in embodiments.

At least one computer-readable storage medium may include instructions that, when executed, cause a system to perform any of the computer-implemented methods described herein.

Some embodiments may be described using the expression “one embodiment” or “an embodiment” along with their derivatives. These terms mean that a particular feature, structure, or characteristic described in connection with the embodiment is included in at least one embodiment. The appearances of the phrase “in one embodiment” in various places in the specification are not necessarily all referring to the same embodiment. Moreover, unless otherwise noted the features described above are recognized to be usable together in any combination. Thus, any features discussed separately may be employed in combination with each other unless it is noted that the features are incompatible with each other.

### Terminology

Tool Implant Metrics—Items that are measured to confirm wafer will be implanted as expected, e.g., energy, species, charge, ROI current, beam height, beam width, angles, angle spread, etc.

Control Inputs/Tuning Knobs—Set of parameters used to create desired Tool Implant Metrics, e.g., Accel, Manipulator position, Analyzer Current, Focus Voltage, Extraction Voltage, Q3, Corrector Current, etc.

Dependent Outputs—parameters which vary with control inputs but are not part of the set of process metrics. For example, using a current controller setting as an input, but use its voltage feedback as a dependent output for inferring impedance.

Stress Vector—set of parameters that measure wear and tear on tool, e.g., extraction current & voltage hours by species, gas flow rates, pump/vent cycles, robot moves, etc.

Guide Star Alignment (GSA) —the use of specific setups to do long optical baseline alignment such as source magnet to filter magnet to manipulator to analyzer to corrector to MPXL beam X offset.

Perturbation Sequences for Alignment and Calibration (PSAC) —single GSA can be inconclusive due to combined interactions of Manipulator, Analyzer Current (multiple unknowns). Orthogonal perturbations can provide sufficient ‘multiple equations’ for solving ‘multiple unknowns’ for n-dimensional calibration

Process Param Sieve—Large set of process params (Metrics) derived from training set and/or forward process model stored as large vector set (˜100,000). As customers pin down aspects of desired process params, the set intersection is calculated, with user input restricted to set intersection. This makes sure that the desired process parameters can be achieved by the tool. Can be used offline and displayed as set of micro histograms that adjust to process param windows

Back Propagation (Stochastic) —working backwards from outputs to inputs, assessing what minor nudge to previous layer results in a move towards the desired output (i.e. do a better job predicting the output). These are done in batches, with the nudges stochastically combined.

Locked Layer Learning—Allows Back Propagation to pass through Neural Net (NN) layers for the purpose of updating only those layers that are not locked

Gradient Based Saliency Map—back propagation of an output difference or perturbation to identify the most important inputs that affected that difference

Regression Neural Network—unlike a classifier network, which uses a Boolean activation function (each neuron evaluates to 0 or 1), a regression NN uses a linear activation function (a bias plus a sum of all values connecting from previous layer). The result is a continuous output value

Transfer Learning—Model trained on one thing can be repurposed to do a related task

Invertible Neural Network (INN) —If input layer variation always results in unique outputs, the model can be run forward to create a training set where the outputs become the inputs. If there are cases where output may be duplicated for 2 or more different inputs, we have two options for inverting the model: (1) Identify duplicates, score them and eliminate all but best output; and (2)»Introduce an attribute to the output layer that categorizes each one of the duplicates appropriately.

The following examples pertain to further embodiments, from which numerous permutations and configurations will be apparent.

It is emphasized that the Abstract of the Disclosure is provided to allow a reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus the following claims are hereby incorporated into the Detailed Description, with each claim standing on its own as a separate embodiment. In the appended claims, the terms “including” and “in which” are used as the plain-English equivalents of the respective terms “comprising” and “wherein,” respectively. Moreover, the terms “first,” “second,” “third,” and so forth, are used merely as labels, and are not intended to impose numerical requirements on their objects.

The foregoing description of example embodiments has been presented for the purposes of illustration and description. It is not intended to be exhaustive or to limit the present disclosure to the precise forms disclosed. Many modifications and variations are possible in light of this disclosure. It is intended that the scope of the present disclosure be limited not by this detailed description, but rather by the claims appended hereto. Future filed applications claiming priority to this application may claim the disclosed subject matter in a different manner, and may generally include any set of one or more limitations as variously disclosed or otherwise demonstrated herein.

What is claimed is:

1. A method, comprising:
receiving a set of process parameters and associated values for an ion implanter by an inverted control model, the inverted control model comprising an artificial neural network (ANN);
predicting a set of control parameters and associated values for the ion implanter based on the set of process parameters and associated values by the inverted control model; and
presenting the set of control parameters and associated values on a graphical user interface (GUI) of an electronic display.

2. The method of claim 1, wherein the inverted control model is trained on a training dataset generated from a control model trained to receive input control vectors and predict output process vectors, wherein duplicate data points are removed from the training dataset.

3. The method of claim 1, wherein the inverted control model is trained on an inverted training dataset generated from a control model trained to receive input control vectors and predict output process vectors and a qualifier control model trained to receive the input control vectors and predict output qualifier vectors, wherein duplicate data points are removed from the inverted training dataset based on one or more qualifier parameters from the output qualifier vectors.

4. The method of claim 1, wherein each control parameter corresponds to a hardware or software setting that controls a configuration or operation of a component of the ion implanter.

5. The method of claim 1, wherein each control parameter comprises a charge parameter, an energy parameter, an acceleration or deceleration parameter, a dopant and flow parameter, a diluent and flow parameter, a source parameter, an analyzer parameter, a corrector parameter, a suppression parameter, a focus parameter, a scan parameter, a quadrupole lens current parameter, or a post-acceleration voltage parameter.

6. The method of claim 1, wherein each process parameter corresponds to a metric associated with a beam property for an ion beam generated by the ion implanter.

7. The method of claim 1, wherein each process parameter comprises a beam height parameter, a beam width parameter, full half height maximum (FHHM) parameter, a vertical within device angle (VWIDA) parameter, a VWIDA mean (VWIDAM) parameter, a horizontal within device angle (HWIDA) parameter, a HWIDA mean (HWIDAM) parameter, a standard deviation of VWIDA (VWIDAS) parameter, a standard deviation of HWIDA mean (HWIDAS) parameter, a vacuum interface (VI) parameter, a width (full not half) parameter, a spotscore parameter, an energy parameter, a region of interest (ROI) current parameter, or a uniformity parameter.

8. The method of claim 1, wherein the inverted control model comprises a regression neural network comprising one input layer, one or more hidden layers, and an output layer, where each neuron in the one or more hidden layers performs computations on input data using a linear activation function to generate a continuous output value, the linear activation function comprising a rectified linear unit (ReLU) function, a leaky ReLU function, or a parametric ReLU function.

9. The method of claim 1, comprising configuring a component of the ion implanter based on the set of control parameters.

10. A method, comprising:
training a control model on a first training dataset comprising multiple data points, each data point comprising an input control vector and an output process vector, the input control vector comprising values for control parameters of an ion implanter, and the output process vector to comprise values for process parameters of the ion implanter;
training a qualifier control model on a second training dataset comprising the multiple data points of the first training dataset, each data point comprising the input control vector, the output process vector, and an output qualifier vector associated with the output process vector;
generating a third training dataset using the trained control model and the trained qualifier control model, the third training dataset comprising multiple data points, each data point comprising an input control vector, an output process vector, and an output qualifier vector;
identifying duplicate data points in the third training dataset, the duplicate data points to comprise multiple data points having a shared output process vector for different input control vectors; and
removing the duplicate data points from the third training dataset based on an output qualifier vector for the duplicate data points to form an inverted training dataset suitable for training an inverted control model.

11. The method of claim 10, comprising training the inverted control model on the inverted training dataset comprising multiple data points, each data point comprising a unique input process vector corresponding to a unique output control vector.

12. The method of claim 10, comprising:
mapping input control vectors and output process vectors from data points of the third training dataset to a shared vector space;
generating a similarity score for each input control vector and each output process vector based on a measure of distance between vectors; and
identifying duplicate data points based on the similarity scores.

13. The method of claim 10, comprising:
combining an output process vector and an output qualifier vector for each data point of the third training dataset into a combined vector;
mapping input control vectors and combined vectors from data points of the third training dataset to a shared vector space;
generating a similarity score for each input control vector and each combined vector based on a measure of distance between vectors; and
identifying duplicate data points based on the similarity scores.

14. The method of claim 10, comprising:
determining a difference value between a first output process vector of a first data point and a second output process vector of a second data point from the third training dataset is below a first defined threshold value;
determining a difference value between a first input control vector of the first data point and a second input control vector of the second data point is above a second defined threshold value; and
identifying the first data point and the second data point as duplicate data points, the first input control vector and the second input control vector as the different input control vectors, and the first output process vector and the second output process vector as the shared output process vector.

15. The method of claim 10, comprising:
eliminating the duplicate data points from the third training dataset based on an output qualifier vector for the duplicate data points; and
removing the output qualifier vectors from the third training dataset prior to training the inverted control model.

16. The method of claim 10, comprising:
retaining the duplicate data points in the third training dataset; and
retaining the output qualifier vectors in the third training dataset prior to training the inverted control model.

17. An ion implanter, comprising:
an ion source to generate an ion beam;
at least one beamline component to direct the ion beam towards a substrate;
a processing circuitry; and
a memory communicatively coupled to the processing circuitry, the memory storing instructions that, when executed by the processing circuitry, causes the processing circuitry to:
receive a set of process parameters and associated values for the ion implanter by an inverted control model, the inverted control model comprising an artificial neural network (ANN); and
predict a set of control parameters and associated values for the ion implanter based on the set of process parameters and associated values by the inverted control model.

18. The ion implanter of claim 17, wherein the inverted control model is trained on an inverted training dataset generated from a control model trained to receive input control vectors and predict output process vectors and a qualifier control model trained to receive the input control vectors and predict output qualifier vectors, wherein duplicate data points are removed from the inverted training dataset based on one or more qualifier parameters from the output qualifier vectors.

19. The ion implanter of claim 17, wherein the inverted control model comprises a regression neural network comprising one input layer, one or more hidden layers, and an output layer, where each neuron in the one or more hidden layers performs computations on input data using a linear activation function to generate a continuous output value, the linear activation function comprising a rectified linear unit (ReLU) function, a leaky ReLU function, or a parametric ReLU function.

20. The ion implanter of claim 17, the processing circuitry to configure the at least one beamline component of the ion implanter based on the set of control parameters.
